(19) United States
(12) Patent Application Publication
(10) Pub. No.: US 2017/0076972 A1
(43) Pub. Date: Mar. 16, 2017

(54) PLANETARY WAFER CARRIERS

(71) Applicant: Veeco Instruments Inc., Plainview, NY (US)

(72) Inventors: Sandeep Krishnan, Jersey City, NJ (US); Lukas Urban, Boulder, CO (US); Alexander Gurary, Bridgewater, NJ (US); Keng Moy, Basking Ridge, NJ (US); Ajit Paranjpe, Basking Ridge, NJ (US)

(21) Appl. No.: 15/266,308

(22) Filed: Sep. 15, 2016

Related U.S. Application Data
(60) Provisional application No. 62/218,886, filed on Sep. 15, 2015.

(51) Int. Cl. H01L 21/687

(52) U.S. Cl. CPC H01L 21/68771; H01L 21/68757; H01L 21/68764

(57) ABSTRACT

A wafer carrier for a plurality of wafers, the wafer carrier having a platen with a plurality of openings and a plurality of wafer retention platforms, the platen configured to rotate about a first axis, the plurality of wafer retention platforms configured to rotate about respective second axes, each of the wafer retention platforms rotatably coupled to one of the plurality of openings by friction reducing bearings, the platen and the plurality of wafer retention platforms and the friction reducing bearings all being constructed of the same material.

### RELATED APPLICATION INFORMATION

This application claims the benefit of U.S. Provisional Application 62/218,886, filed Sep. 15, 2015, which is hereby incorporated by reference.

### TECHNICAL FIELD

The present disclosure relates generally to processing apparatuses and methods for semiconductor wafer fabrication. More particularly, the present disclosure relates to wafer carriers for use in such processing apparatuses and methods for semiconductor wafer fabrication.

### BACKGROUND

Certain processes for fabrication of semiconductors can require a complex process for growing epitaxial layers to create multilayer semiconductor structures for use in fabrication of high performance devices, such as light emitting diodes, laser diodes, optical detectors, power electronics, and field effect transistors. In this process, the epitaxial layers are grown through a general process called Chemical Vapor Deposition (CVD). One type of CVD process is called Metal Organic Chemical Vapor Deposition (MOCVD). In MOCVD, a reactor gas is introduced into a sealed reactor chamber within a controlled environment that enables the reactor gas to be deposited on a substrate (commonly referred to as a wafer) to grow thin epitaxial layers. Examples of current product lines for such manufacturing equipment include the TurboDisc®, MaxBright®, the EPIK® families of MOCVD systems, and the PROPEL® Power GaN MOCVD system, all manufactured by Veeco Instruments Inc. of Plainview, N.Y.

During epitaxial layer growth, a number of process parameters are controlled, such as temperature, pressure, and gas flow rate, to achieve desired quality in the epitaxial layer. Different layers are grown using different materials and process parameters. For example, devices formed from compound semiconductor, such as III-V semiconductors, typically are formed by growing a series of distinct layers. In this process, the wafers are exposed to a combination of gases, typically including a metal organic compound as a source of group III metal, and also including a source of group V element which flow over the surface of the wafer while the wafer is maintained at an elevated temperature. Generally, the metal organic compound and group V source are combined with a carrier gas which does not participate appreciably in the reaction, for example, nitrogen or hydrogen. One example of a III-V semiconductor is gallium nitride, which can be formed by reaction of organo-gallium compounds and ammonia on a substrate having a suitable crystal lattice spacing, for example a sapphire or silicon wafer. The wafer is usually maintained at a temperature on the order of 700-1200° C. during the deposition of the gallium nitride and/or related compounds. Another example of III-V semiconductor is indium phosphide (InP), which can be formed by reaction of indium and phosphine. Yet another is aluminum gallium arsenide (AlGa₁₋ₓAsₓ), which can be formed by the reaction of aluminum, gallium and arsine. The reaction of these compounds forms a semiconductor layer on a suitable substrate.

In general, III-V compounds can have the general formula In_{X}Ga_{Y}Al_{Z}N_{A}As_{B}P_{C}Sb_{D}, where X+Y+Z equals approximately one, A+B+C+D equals approximately one, and each of X, Y, Z, A, B, C, and D can be between zero and one. In some instances, bismuth may be used in place of some or all of the other Group III metals. Suitable substrate can be a metal, semiconductor, or an insulating substrate and can include sapphire, aluminum oxide, silicon (Si), silicon carbide (SiC), gallium arsenide (GaAs), indium phosphide (InP), indium arsenide (InAs), gallium phosphide (GaP), aluminum nitride (AlN), silicon dioxide (SiO2), and the like.

Another type of CVD process involves the growth of silicon carbide layers on substrates to form power electronic devices. Silicon carbide layers are grown using silanes and hydrocarbons as the reactive species with hydrogen as a carrier gas. The wafer is usually maintained at a temperature on the order of 800-2000° C. during deposition.

To aid in the uniformity of epitaxial growth, one or more semiconductor wafers on which the epitaxial layers are to be grown can be placed on a rapidly-rotating carousel, often referred to as wafer carrier, so that the top surface of each wafer is exposed, thereby providing a uniform exposure of the top surface of the wafer to the atmosphere within the reactor chamber for the deposition of semiconductor materials. The wafer carrier is commonly rotated at a rotation speed on the order from about 100 to 1500 RPM or higher. This rapid rotation provides a more uniform exposure of the wafer surfaces to the atmosphere within the reactor chamber for the deposition of the epitaxial layers. The wafer carriers can be machined out of a highly thermally conductive material such as graphite, and are often coated with a protective layer of material such as silicon carbide. Each wafer carrier can have a set of circular indentations, or pockets, and its top surface in which the individual wafers are placed. Some examples of pertinent technology are described in U.S. Patent Publ. Nos. 2007/0186853 and 2012/0040097, and U.S. Pat. Nos. 6,492,625; 6,506,252; 6,902,623; 8,021,487; and 8,092,599, the disclosures of which are incorporated by reference herein. Other wafer carriers have a single pocket in which a single wafer is placed.

In some cases, the wafer carrier is supported on a spindle within the reactor chamber so that the top surface of the wafer carrier having the exposed surfaces of the wafers faces upwardly toward a gas distribution device. While the spindle is rotated, the gas is directed downwardly onto the top surface of the wafer carrier and flows across the top surface toward the periphery of the wafer carrier. The used gas can be evacuated from the reaction chamber through ports disposed below the wafer carrier.

In some cases, the wafer carrier can be supported and rotated by a rotational system that does not require a spindle, for example, a rotating dielectric support in the form of a hollow cylinder coupled to the top of a turntable. A rotation system of this type is described in U.S. Patent Publ. No. 2015/0075431, the contents of which are hereby incorporated by reference herein. In yet other cases, the wafer carrier can be placed facedown (inverted) in the reaction chamber and the gas injectors are mounted below the wafer carrier such that the gas mixture flows upwardly towards the one or more wafers. Examples of such inverted gas injection systems are described in U.S. Patent Publ. Nos. 2004/0060518 and 2004/0175939, and U.S. Pat. No. 8,133,322, the contents of which are hereby incorporated by reference herein.

In an effort to improve deposition uniformity, in addition to rotation of the wafer carrier, some wafer carriers configured to hold multiple wafers are configured to rotate the wafers relative to the wafer carrier, thus creating a planetary motion of the wafers in the wafer carrier. An example of such a planetary wafer carrier is described in U.S. Patent Publ. No. 2008/0102199, the contents of which are hereby incorporated by reference herein.

The wafer carrier can be maintained at the desired elevated temperature by heating elements, typically electric resistive heating elements disposed below the bottom surface of the wafer carrier. These heating elements are maintained at a temperature above the desired temperature of the wafer surfaces, where as the gas distribution device typically is maintained at a temperature well below the desired reaction temperature, so as to prevent premature reaction of the gases. Therefore, heat is transferred from the heating elements to the bottom surface of the wafer carrier and flows upwardly through the wafer carrier to the one or more wafers. Heat transferred upwards through the carrier material is also radiated from the top surface of the wafer carrier. The degree of radiation heat transfer from the wafer carrier is a function of the emissivity of the various surfaces of carrier and the surrounding components (e.g., the protective layer, wafers, and deposited films).

During the CVD process it is beneficial to maintain uniform conditions at all points on the surfaces of the one or more wafers. Minor variations in composition of the reactive gases and in the temperature of the wafer surfaces can cause undesired variations in the properties of the resulting semiconductor device. For example, if a gallium and indium nitride layer is deposited, variations in wafer surface temperature can cause variations in the composition and the bandgap of the deposited layer. Because indium has a relatively high vapor pressure, the deposited layer can have a lower proportion of indium and a greater bandgap in those regions of the wafer where the surface temperature is higher. If the deposited layer is an active, light-emitting layer of an LED structure, the emission wavelength of the LEDs formed from the wafer will also vary. These effects contribute to a reduced product yield.

Although considerable effort has been devoted in the art heretofore to optimize such CVD systems, still further improvement is desirable. In particular, it would be desirable to provide better uniformity of temperature across the surface of each wafer, and better temperature uniformity across the entire wafer carrier for the purpose of reducing epitaxial growth non-uniformities among, and across each of the surfaces of the wafers.

Moreover, given the complexity of wafer carriers, particularly those configured to rotate the individual wafers within the rotating wafer carrier, cleaning of the wafer carrier can be an involved and complicated process. The complexity of the rotational mechanics can also negatively impact the usable lifetime of the wafer carriers. Accordingly, it would be desirable to provide a wafer carrier with a simpler mechanical design that reduces cleaning requirements and extends the usable lifetime of the wafer carrier.

### SUMMARY OF THE DISCLOSURE

Various embodiments of the present disclosure provide a chemical vapor deposition (CVD) system in which the uniformity of the temperature across the wafer carrier, and the surfaces of each of the surfaces of the wafers therein, is improved, thereby reducing epitaxial growth non-uniformities among and across each of the surfaces of the wafers. For example, in effort to reduce temperature non-uniformities caused by the use of materials with different thermal conductivities, in one embodiment, the wafer carrier can be constructed of a platen and plurality of wafer retention platforms constructed of a like material, such as silicon carbide. In this embodiment, each of the plurality of wafer retention platforms can be rotatably coupled to the platen by a friction reducing bearing assembly constructed of the same material as the platen and wafer retention platform, thereby eliminating the use of dissimilar materials, such as screws, bolts or other fasteners, to construct the wafer carrier. To further improve temperature uniformity, in one embodiment, the friction reducing bearing assemblies can be positioned on the radial outer edge of each of the wafer retention platforms. In some embodiments, constructing the wafer carrier of a like material can additionally reduce sensitivity to thermal expansion and potential sizing issues as a result of operation at high temperatures.

Various embodiments of the present disclosure further provide a CVD system with the wafer carrier configured to rotate the wafers relative to the wafer carrier, thus creating a planetary motion of the wafers in the wafer carrier, without the use complex drive systems constructed of materials with different thermal conductivities. For example, in one embodiment, a portion of each of the plurality of wafer retention platforms is configured as a planetary gear driven by a central sun gear, thereby eliminating the need for a separate drive system constructed of a different material. In another embodiment, the need for planetary gearing is eliminated through the use of a ring driver assembly. In yet another embodiment, the need for gearing to rotate the individual wafers can be eliminated by the use of a gas flow to impart rotation.

One embodiment of the present disclosure provides a wafer carrier for a plurality of wafers. The wafer carrier can include a platen and a plurality of wafer retention platforms. The platen can include a plurality of openings and can be configured to rotate about a first axis. Each of the plurality of wafer retention platforms can be rotatably coupled to one of the plurality of openings by a friction reducing bearing assembly, such that each of the plurality of wafer retention platforms can be configured to rotate about a respective second axis. The platen, the plurality of wafer retention platforms and the friction reducing bearing assemblies can be constructed of the same material.

In some embodiments, the platen, plurality of wafer retention platforms and the friction reducing bearing assemblies can be constructed of silicon carbide. In some embodiments, each of the friction reducing bearing assemblies can comprise a plurality of ball bearings, wherein the ball bearings reside within a ball bearing channel defined between an inner circumferential surface of the plurality of openings of the platen and an outer circumferential surface of each of the plurality of wafer retention platforms. In some embodiments, the plurality of ball bearings can be inserted into the ball bearings channel via one or more bearing filling channels. In some embodiments, the one or more bearing filling channels can be plugged by one or more channel plugs after the plurality of ball bearings are inserted.

In some embodiments, the platen can rotate at a first rotational speed and at least one of the plurality of wafer retention platforms can rotate at a second rotational speed. In some embodiments, each of the wafer retention platforms can comprise a planetary gear. In some embodiments, each of the planetary gears can be rotated by a centrally located sun gear. In some embodiments, the sun gear can be constructed of silicon carbide. In some embodiments, the sun gear can be operably coupled to the platen via a sun gear friction reducing bearing. In some embodiments, the sun gear friction reducing bearing can comprise a plurality of ball bearings, wherein the ball bearings reside within a sun gear ball bearing channel defined between a portion of the platen and a portion of the sun gear. In some embodiments, the plurality of ball bearings can be inserted into the sun gear ball bearings channel via one or more sun gear bearing filling channels. In some embodiments, sun gear bearing filling channels can be plugged by a channel plug after the ball bearings are inserted. In some embodiments, the platen and the sun gear can be independently rotated by a dual core motor.

Another embodiment of the present disclosure provides a wafer carrier for a plurality of wafers. The wafer carrier can include a platen and a plurality of wafer retention platforms. The platen can include a plurality of openings and a plurality of bearing filling channels. The platen can be configured to rotate about a first axis. Each of the plurality of wafer retention platforms can be rotatably coupled to one of the plurality of openings by a plurality of ball bearings added through the plurality of bearing filling channels and can be configured to rotate about a respective second axis.

In some embodiments, the platen, plurality of wafer retention platforms and plurality of ball bearings can be constructed of silicon carbide. In some embodiments, the ball bearings can reside within a ball bearing channel defined between an inner circumferential surface of the plurality of openings of the platen and an outer circumferential surface of each of the plurality of wafer retention platforms. In some embodiments, the plurality of bearing filling channels can be plugged by one or more channel plugs after the plurality of ball bearings are added. In some embodiments, the platen can rotate a first rotational speed and at least one of the plurality of wafer retention platforms can rotate at a second rotational speed.

In some embodiments, each of the plurality of wafer retention platforms can comprise a planetary gear. In some embodiments, at least one of the planetary gears can be rotated by a centrally located sun gear. In some embodiments, the sun gear can be constructed of silicon carbide.

Another embodiment of the present disclosure provides a wafer carrier for a plurality of wafers. The wafer carrier can include a platen, plurality of wafer retention platforms and one or more ring drivers. The platen can be configured to rotate about a first axis and can have a plurality of openings organized along one or more circumferential rings centered on the first axis. Each of the plurality of wafer retention platforms can have a hub, wherein each wafer retention platform is rotatably coupled to one of the plurality of openings and is configured to rotate relative to the platen about its hub. The one or more ring drivers can be rotatably coupled to the platen and can be configured to engage the hubs of the wafer retention platforms organized along at least one of the circumferential rings, so as to rotate the wafer retention platforms about their respective hubs.

In some embodiments, a differential in rotational speed between the platen and the one or more ring drivers can cause the platen to rotate at a first rotational speed and the wafer retention platforms to rotate at a second rotational speed. In some embodiments, two ring drivers can be configured to rotate a first set of wafer retention platforms organized along an inner circumferential ring centered on the first axis of the platen about their respective hubs, and a second set of wafer retention platforms organized along an outer circumferential ring centered on the first axis of the platen about their respective hubs. In some embodiments, the first set of wafer retention platforms can rotate about the respective hubs at a first rotational speed, and the second set of wafer retention platforms can rotate about the respective hubs at a second rotational speed. In some embodiments, the platen and each of the plurality of wafer retention platforms can be coupled to one another via a friction reducing assembly. In some embodiments, the platen and the one or more ring drivers can be independently rotated by a dual core motor.

Another embodiment of the present disclosure provides a wafer carrier for a plurality of wafers. The wafer carrier can include a platen and a plurality of wafer retention platforms. The platen can have a plurality of openings, and can be configured to rotate about a first axis. Each of the wafer retention platforms can be rotatably coupled to a respective one of the plurality of openings. Each of the wafer retention platforms can include a set of blades and can be configured to rotate about a respective second axis when a force is applied to its set of blades.

In some embodiments, each blade of the respective sets of blades can be shaped to produce the desired rate of rotation of its respective wafer retention platform. In some embodiments, each of the wafer retention platforms can be coupled to the platen via a friction reducing bearing. In some embodiments, the silicon wafer can be positioned in each wafer retention platform. In some embodiments, the silicon wafer and wafer retention platform can have a combined weight 300 grams or less. In some embodiments, one or more nozzles can be directed at the sets of blades, so as to apply a fluid flow force on the blades.

The summary above is not intended to describe each illustrated embodiment or every implementation of the present disclosure. The figures and the detailed description that follow more particularly exemplify these embodiments.

### BRIEF DESCRIPTION OF THE DRAWINGS

FIG. 1 is a diagrammatic view depicting a multi-wafer rotating disk reactor in accordance with an embodiment of the disclosure;

FIG. 2 is a perspective view depicting a wafer carrier and motor assembly in accordance with an embodiment of the disclosure;

FIG. 3 is a perspective view depicting the top of a platen in accordance with an embodiment of the disclosure;

FIG. 4 is a perspective view depicting the bottom of the platen of FIG. 3;

FIG. 5 is an elevation view depicting a wafer retention platform and planetary gear combination in accordance with an embodiment of the disclosure;

FIG. 6 is a perspective view depicting the top of the wafer retention platform and planetary gear combination of FIG. 5;

FIG. 7 is a perspective view depicting the bottom of the wafer retention platform and planetary gear combination of FIG. 5;

FIG. 8 is a perspective view depicting the top of a sun gear in accordance with an embodiment of the disclosure;

FIG. 9 is a perspective view depicting the bottom of wafer carrier, showing planetary and sun gears in accordance with an embodiment of the disclosure;

FIG. 10 is a partial exploded perspective view depicting the top of a wafer carrier assembly in accordance with an embodiment of the disclosure;

FIGS. 10A-B are perspective views depicting the plugs in accordance with an embodiment of the disclosure;

FIGS. 10C-D are perspective views depicting the top and bottom of an assembled wafer carrier in accordance with an embodiment of the disclosure;

FIG. 11 is a cross-sectional view depicting an assembled wafer carrier in accordance with an embodiment of the disclosure;

FIG. 12 is a perspective view depicting an planet filling hole plug in accordance with an embodiment of the disclosure;

FIG. 13 is a cross-sectional view depicting a portion of an assembled wafer carrier in accordance with an embodiment of the disclosure;

FIG. 14 is a perspective view depicting an sun filling hole plug in accordance with an embodiment of the disclosure;

FIG. 15 is a cross-sectional view depicting an assembled wafer carrier in accordance with an embodiment of the disclosure;

FIGS. 16, 16A and 16B are a cross-sectional views depicting an assembled wafer carrier in accordance with an embodiment of the disclosure;

FIGS. 17-19 are a cross-sectional perspective views depicting an assembled wafer carrier in accordance with an embodiment of the disclosure;

FIGS. 20, 20A and 20B are a cross-sectional views depicting an assembled wafer carrier in accordance with an embodiment of the disclosure;

FIG. 21 is a perspective view depicting the top of a dual core motor in accordance with an embodiment of the disclosure;

FIG. 22 is a perspective view depicting the bottom of a platen and primary spindle hub in accordance with an embodiment of the disclosure;

FIG. 23 is a perspective view depicting the top of a sun gear coupled to a dual core motor in accordance with an embodiment of the disclosure;

FIG. 24 is a cross-sectional view depicting a wafer carrier coupled to a dual core motor in accordance with an embodiment of the disclosure;

FIG. 25 is a cross-sectional view depicting a dual core motor in accordance with an embodiment of the disclosure;

FIG. 26 is a cross-sectional view depicting a wafer carrier coupled to a dual core motor in accordance with an embodiment of the disclosure;

FIG. 27 is an elevation view depicting a wafer carrier coupled to a dual core motor in accordance with an embodiment of the disclosure;

FIGS. 28-32 are plan views depicting wafer carrier assemblies in accordance with example embodiments of the disclosure;

FIG. 33 is a plan view depicting a multi-ring wafer carrier assembly in accordance with an embodiment of the disclosure;

FIG. 33A is a cross-sectional view depicting a multi-ring wafer carrier assembly in accordance with an embodiment of the disclosure;

FIG. 34A is a top plan view depicting a multi-ring wafer carrier assembly in accordance with an embodiment of the disclosure;

FIG. 34B is a bottom view depicting the multi-ring wafer carrier assembly of FIG. 34A;

FIGS. 35 and 35A are views depicting a wafer carrier assembly in accordance with example embodiments of the disclosure;

FIG. 36A is a top plan view depicting a gas driven wafer retention platform in accordance with an embodiment of the disclosure;

FIG. 36B is a bottom view depicting a gas driven wafer retention platform in accordance with an embodiment of the disclosure;

FIG. 37 is a cross-sectional view depicting a wafer carrier with gas driven wafer retention platforms in accordance with an embodiment of the disclosure;

FIG. 37A is a detailed view depicting a wafer carrier with gas driven wafer retention platforms in accordance with an embodiment of the disclosure;

FIG. 38 is a detailed view depicting a wafer carrier with gas driven wafer retention platforms in accordance with an embodiment of the disclosure;

FIG. 39 is a diagrammatic view depicting a wafer carrier with gas driven wafer retention platforms in accordance with an embodiment of the disclosure; and

FIG. 40 is a perspective view depicting the bottom of the wafer carrier with gas driven wafer retention platforms in accordance with an embodiment of the disclosure.

While embodiments of the disclosure are amenable to various modifications and alternative forms, specifics thereof are shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure as defined by the appended claims.

### DETAILED DESCRIPTION

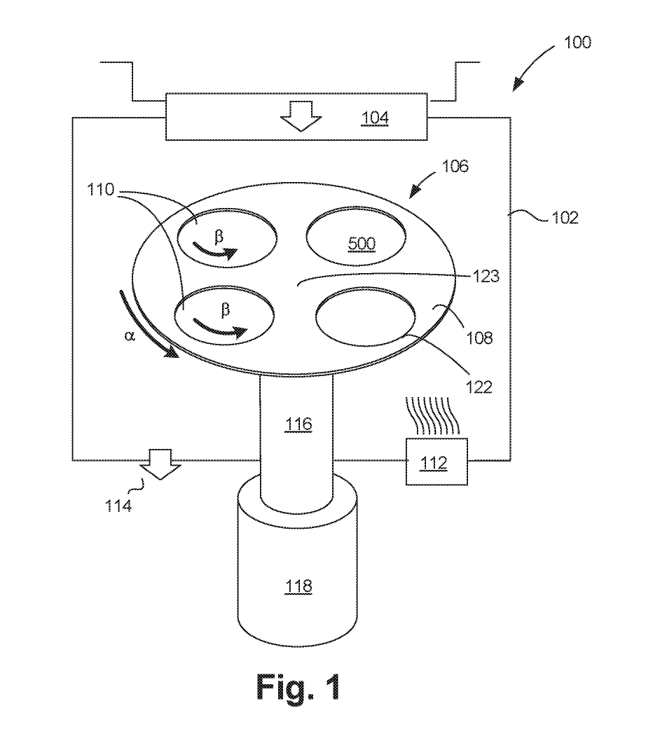

Referring to FIG. 1, a multi-wafer rotating disk reactor 100 is depicted in accordance with an embodiment of the disclosure. Multi-wafer rotating disk reactor 100 generally includes a reaction chamber 102, a flange 104 and a wafer carrier 106. The wafer carrier 106 can include a platen 108 and a plurality of wafer retention platforms 110 on which a plurality of wafers (not depicted) are placed. The wafer carrier 106 serves the purposes of positioning the wafers inside of the reaction chamber 102 as well as support for the wafers during the chemical reaction process.

The flange 104 can be a showerhead coupled with a precursor source to supply one or more precursor gases to reaction chamber 102. In a typical MOCVD system, the precursor gases are composed of a metalorganic gas and the corresponding reacting species required for the chemical reaction. The wafers located inside of reaction chamber 102 on the wafer retention platforms 110 serve as sites for the chemical reaction and subsequent epitaxial growth. The heat required for the chemical reaction is supplied by the heating elements 112. The by-products of the chemical reaction are organic gases, which are released through exhaust ports 114.

There are numerous types of heaters that can be used to supply heat for the chemical reaction transpiring on the wafers. In one embodiment, a radiant heater can be positioned proximate wafer carrier 106 in order to heat the wafers to a desired process temperature. In another embodiment, RF induction coils can be positioned proximate the wafer carrier 106 so that energy from the RF induction coils heat the wafers. In yet another embodiment, the heat required for the chemical reaction can be supplied by a serpentine heating element which can be comprised of, for example infrared heating elements. In yet another embodiment, the heat required for the chemical reaction can be supplied by microwaves. One skilled in the art will appreciate that other types of heaters can be used to heat the wafers. The heater arrangement can be optimized to take advantage of rotational averaging provided by the planetary carrier. For example, the heater elements 112 can be arranged in multiple rings where a ring or set of adjacent rings is independently controllable as a zone. By adjusting the relative power provided to each zone, a uniform wafer temperature can be maintained despite radial non-uniformities in wafer cooling, wafer bow, etc., which are normally encountered in such processes.

In one embodiment, the platen 108 of wafer carrier 106 is seated over a center spindle 116, which is rotated by a motor 118. The motor 118 can provide rotation to center spindle 116 to produce a rate of rotation α. A motive force can also be transmitted through the motion mechanism to the plurality of wafer retention platforms 110, so as to produce a second rate of rotation β.

As the gas emitted from flange 104 naturally settles onto the top of wafer carrier 106. Platen 108 being rotated at rate of rotation α imparts a rotational flow, as well as, a centrifugal force on the boundary layer of gas above platen 108. This centrifugal force causes the gas to flow across the top surface toward the periphery of the wafer carrier 106. The result is improved deposition uniformity across the surface of each wafer. To further improve deposition uniformity, each wafer retention platform 110 is rotated at rate of rotation β. Rotation β inhibits any one side of wafer 500 from continuously being oriented toward the center of platen 108, thereby potentially subjecting that side to a higher rate of deposition during the reaction process. Accordingly, rotation α and rotation β combine to create the effect of rotational averaging for the purpose of improving deposition uniformity, and ultimately reducing or eliminating photo luminescence non-uniformities in finished optical products.

A. Wafer Carrier Constructed of One Material Type

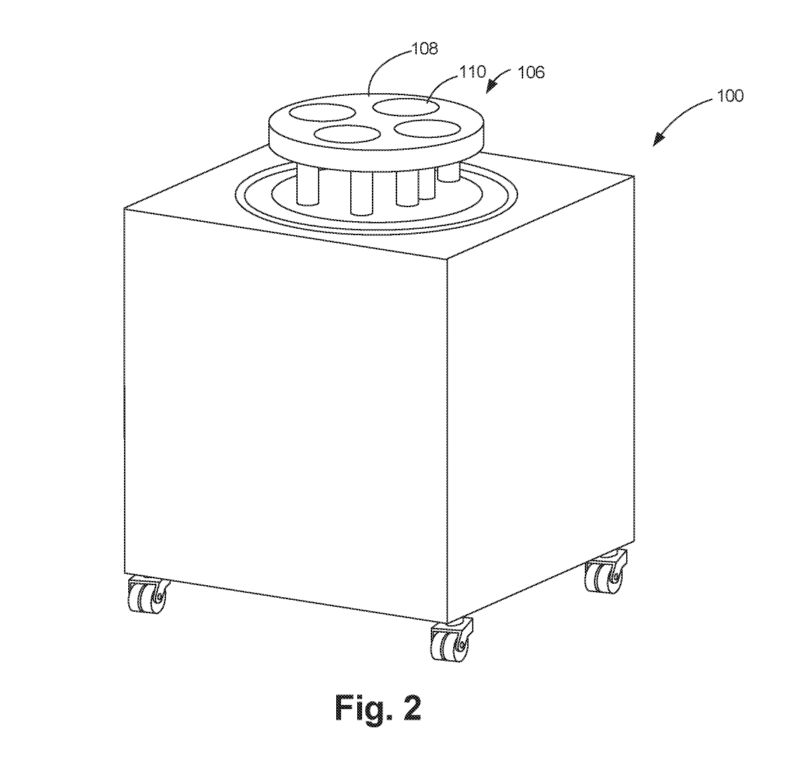

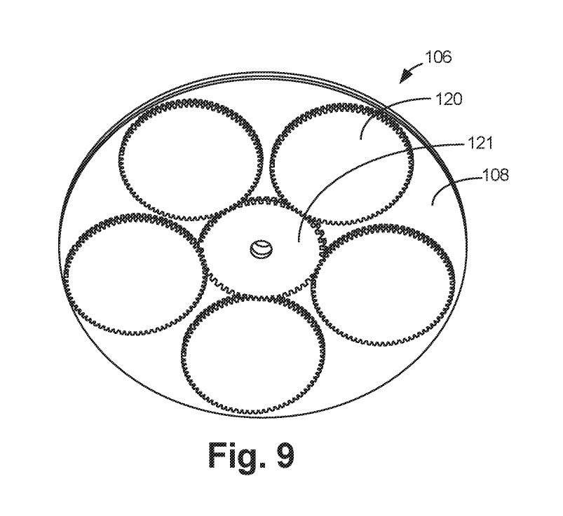

Referring to FIG. 2, in one embodiment, the wafer carrier 106 of multi-wafer rotating disk reactor 100 is a dual drive geared mechanism that is particularly well suited to operate at high temperatures and high RPM. Wafer carrier 106 includes a platen 108, a plurality of wafer retention platforms 110, planetary gears 120, sun gear 121 (e.g., FIG. 9), and associated friction reducing bearings 122, 123 (e.g., FIG. 1). Platen 108 and the plurality of wafer retention platforms 110 are configured to rotate at different rotational speeds from one another via sun 121 and planetary gears 120.

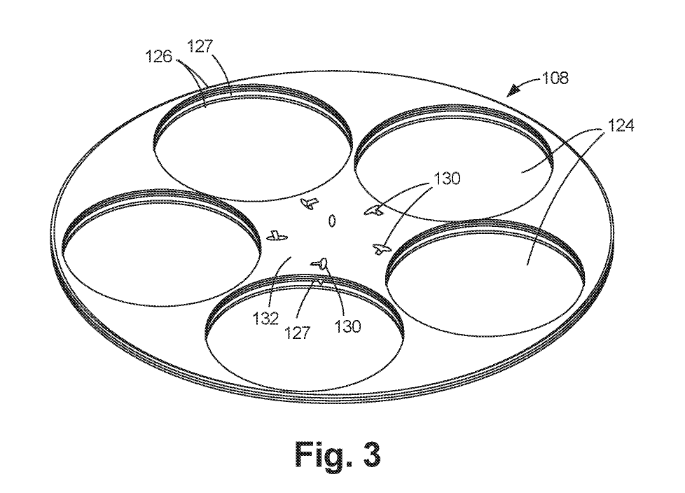

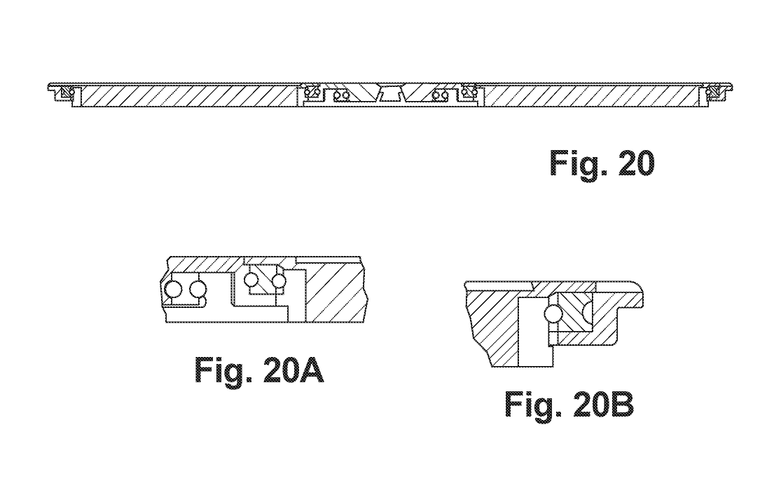

To aid in the operation at high temperatures within reaction chamber 102, the entire wafer carrier 106 can be constructed of a single material, such as silicon carbide. In general, to facilitate the construction of wafer carrier 106 of a single material, one embodiment enables assembly of wafer carrier 106 by filling races or grooves 127, 146, 166, and 170 between rotating parts with ball bearings constructed of the same material. (Discussed in further detail infra attendant to FIGS. 3-20). The races can be filled by a plurality of ball bearing filling channels, which can later be plugged. Accordingly, no screws, bolts or other fasteners or bearings of a different material are employed in the assembly. The use of a single material for wafer carrier 106 reduces sensitivity to thermal expansion and potential sizing issues as a result of operation at high temperatures. Moreover, for embodiments that utilize integrated races, the assembly can be greatly simplified.

Referring to FIG. 3, platen 108 can be formed of a single piece of material. For example, platen 108 can be cast of silicon carbide. Platen 108 is generally disk shaped, and has a plurality of openings 124. Each of the plurality of openings 124 is appropriately sized to accommodate one wafer retention platform 110. The inner circumference of each of the plurality of openings 124 can include one or more substantially smooth portions 126 and a race or groove 127 sized to accommodate a plurality of ball bearings 128.

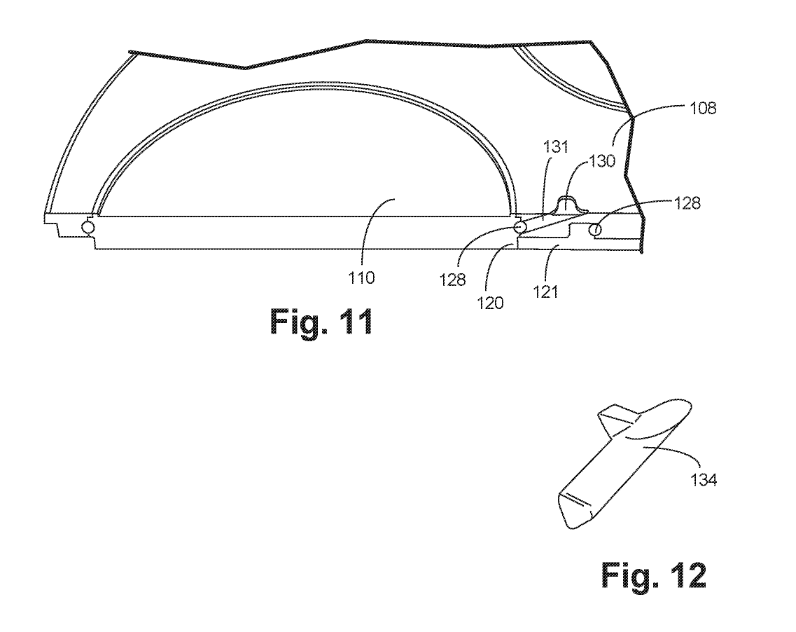

Platen 108 can have a plurality of planet bearing filling channels 130, wherein at least one of each of the plurality of openings 124 is associated with one planet bearing filling channel 130. Planet bearing filling channels 130 include a duct 131 (see FIG. 11), which is appropriately sized to enable ball bearings 128 to pass through duct 131 from the top surface 132 of platen 108 to race 127. The portion of planet bearing filling channel 130 proximate the top surface 132 of platen 108 can be shaped to enable a planet bearing filling channel plug 134 to be inserted for the purpose of blocking the duct 131 of planet bearing filling channels 130.

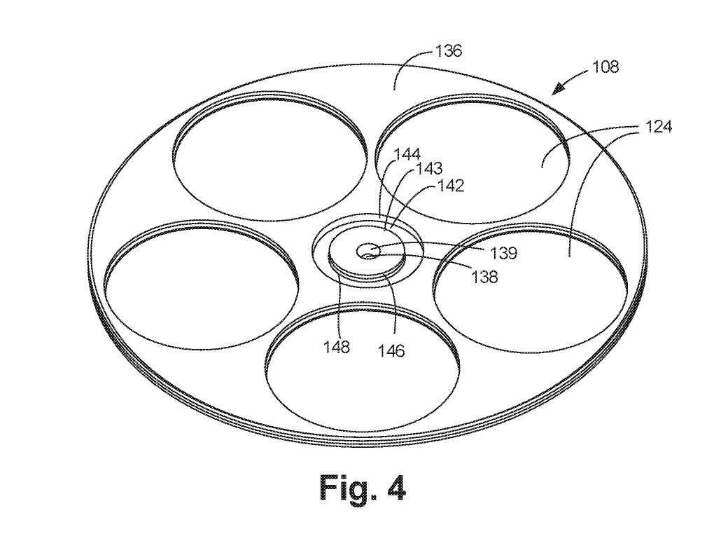

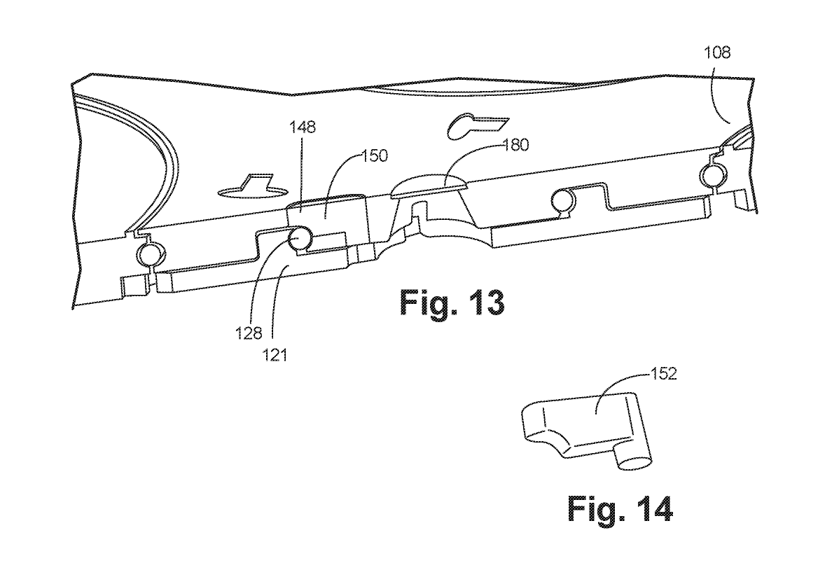

Referring to FIG. 4, the bottom surface 136 of platen 108 can define a center spindle hub receiver 138 proximate the center of platen 108. In one embodiment, center spindle hub receiver 138 is a hole that passes through platen 108. In another embodiment, center spindle hub receiver 138 can be a blind bore. The edge of center spindle hub receiver 139 can be beveled (see FIG. 13), such that the opening of center spindle hub receiver 138 is generally larger proximate the bottom surface of platen 136. The center spindle hub receiver 138 of FIG. 4 is depicted as substantially circular; however, center spindle hub receiver 138 can take a variety of shapes. For example, in FIG. 22, center spindle hub receiver 138 is shaped to mate with center spindle hub 140, such that center spindle hub 140 can be inserted and withdrawn from center spindle hub receiver 138, but is fixed in position relative to wafer carrier 106 when rotated.

The bottom surface 136 of platen 108 can have a recessed sun gear compartment 142. Recessed sun gear compartment 142 can be circular in shape, and can be configured to mate with a portion of sun gear 121. The inner circumference 143 and/or outer circumference 144 of the recessed sun gear compartment 142 can include a race or groove 146 sized to accommodate a plurality of ball bearings 128.

Platen 108 can have one or more sun bearing filling channels 148 that are associated with the recessed sun gear compartment 142. Sun bearing filling channel 148 can include a duct 150 (see FIG. 13), which is appropriately sized to enable ball bearings 128 to pass through duct 150 from the top surface 132 of platen 108 to recessed sun gear compartment 142. The portion of sun bearing filling channel 148 proximate the top surface of platen 132 can be shaped to enable a sun bearing filling channel plug 152 to be inserted for the purpose of blocking the duct 150 of sun bearing filling channel 148.

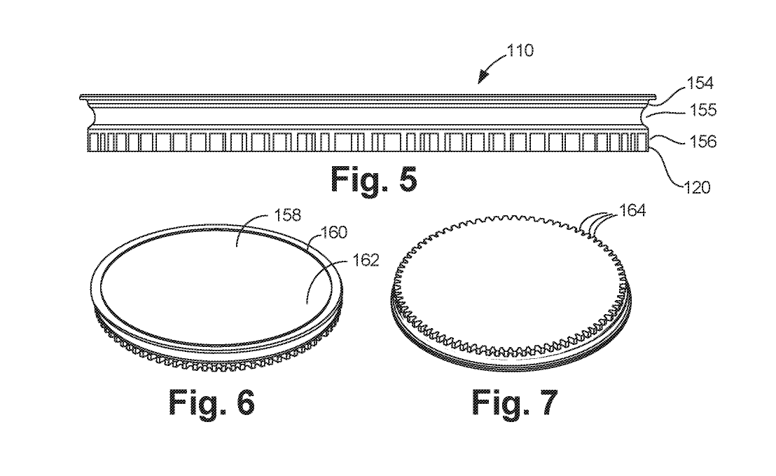

Referring to FIGS. 5-7, each wafer retention platform 110 can have a top portion 154, an intermediate portion 155 and a bottom portion 156. Top portion 154 can be configured to serve as support for wafer during the chemical reaction process. Upper face 158 of top portion 154 can be substantially smooth. Upper face 158 can bound by a lip 160 extending upwards from top portion 154 along the circumference of wafer retention platform 110. The substantially smooth upper face 158 surrounded by lip 160 can provide a pocket 162 for positioning and support of wafer. In some embodiments, the shape of pocket 162 can be contoured to achieve a uniform wafer temperature and to correct for thermal shadowing.

Bottom portion 156 of wafer retention platform 110 can be configured to serve as a planetary gear 120 to rotationally drive retention platform 110. The circumference of bottom portion 156 can be characterized by a plurality of teeth 164, so that bottom portion of each wafer retention platform 110 forms a gear.

Intermediate portion 155 of wafer retention platform 110 can be configured to mate with openings 124 of platen 108. Intermediate portion 155 can be characterized by a race or groove 166 traversing along the outside circumference of the wafer retention platform 110. Race 166 can be sized to accommodate a plurality of ball bearings 128.

As shown in FIGS. 5-7, wafer retention platform 110, including top 154, intermediate 155 and bottom portions 156, can be formed of a single piece of material. For example, wafer retention platform 110 could be cast of silicon carbide. Alternatively, one skilled in the art will appreciate that wafer retention platform 110 can be comprised of multiple pieces affixed together.

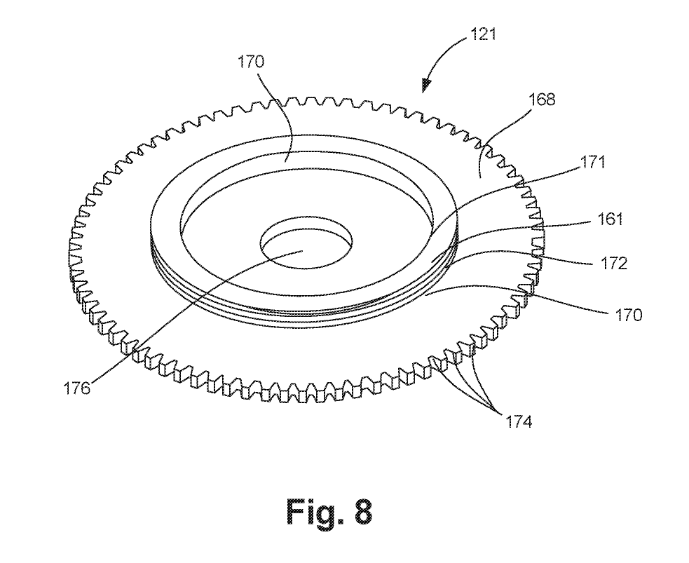

Referring to FIG. 8, sun gear 121 has a top surface 172, characterized by raised portion 169. Raised portion 169 can be circular in shape and is configured to mate with the recessed sun gear compartment 142 of platen 108. Raised portion 169 can also include a race or groove 170 traversing along the inner circumference 171 and/or outer circumference 172 of raised portion 169. Race 170 can be sized to accommodate a plurality of ball bearings 128. Sun gear 121 can further characterized by a plurality of teeth 174 along the circumference of sun gear 121. The center of sun gear 122 can have a secondary spindle receiver 176 shaped and sized to accommodate a secondary spindle 178. Sun gear 121 can be formed of a single piece of material. For example, sun gear 121 could be cast of silicon carbide.

Referring to FIG. 9, when assembled on platen 108, sun gear 121 can be positioned between the plurality of planetary gears 120, such that teeth 174 of sun gear 121 mesh with teeth 164 of each of the planetary gears 120. Accordingly, rotation of the sun gear 121 causes rotation of each of the plurality of planetary gears 120.

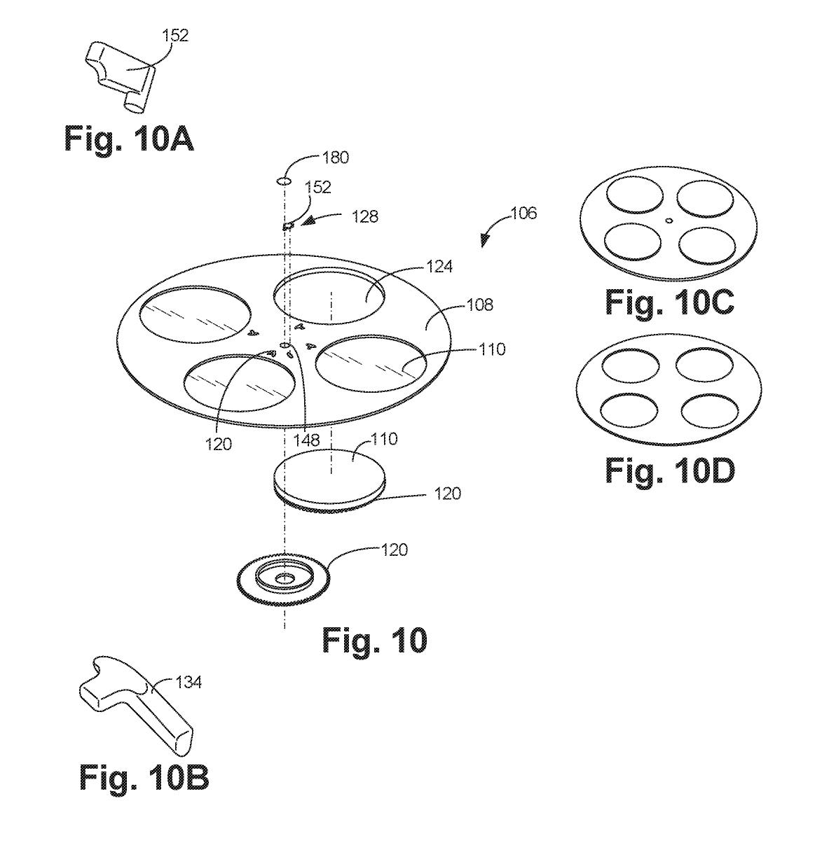

Referring to FIGS. 10, 10A-10D and 11-14, wafer carrier 106, is assembled by positioning each of the plurality of wafer retention platforms 110 in respective openings 124 of platen 108. Each wafer retention platform 110 is secured into position by inserting a plurality of ball bearings 128 into race 127 and 166 via planet bearing filling channel 130. Planet bearing filling channel 130 is then sealed by planet bearing filling channel plug 134. Ball bearings 128 and planet bearing filling channel plug 134 can be made of the same material as the rest of wafer carrier 106, such as silicon carbide. Together, race 127, 166 and ball bearings 128 can form friction reducing bearing 122. See FIGS. 11-12 for a cross-sectional view of the completed assembly.

Sun gear 121 is added to the wafer carrier assembly 106, such that raised portion 169 is mated with the recessed sun gear compartment 142 of platen 108, and the teeth 174 of sun gear 121 mesh with the teeth 164 of the plurality of planetary gears 120. Sun gear 121 is secured into position by inserting a plurality of ball bearings 128 into race 146 and 170 via sun bearing filling channel 148. Sun bearing filling channel 148 is then sealed by sun bearing filling channel plug 152. Ball bearings 128 and sun bearing filling channel plug 152 can be made of the same material as the rest of wafer carrier 106, such as silicon carbide. Together, races 146,170 and ball bearings 128 form friction reducing bearing 123. See FIGS. 13-14 for a cross-sectional view of the completed assembly. A carrier plug 180 can be used to seal the top of center spindle hub receiver 138. The planet bearing filling channel plug 134, sun bearing filling channel plug 152 and carrier plug 180 are designed to lock the assembly in place and to prevent ball bearings 128 from escaping during high speed rotation. All plugs 134, 152, and 180 are considered part of wafer carrier 106, and can be made of the same material as the rest of wafer carrier 106, such as silicon carbide.

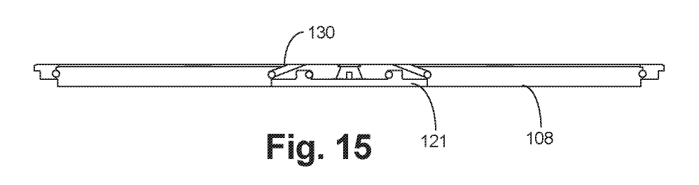

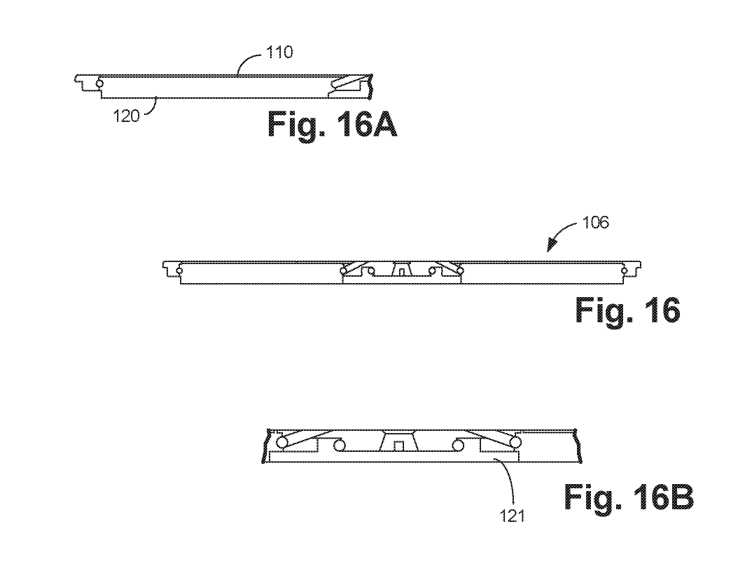

Referring to FIGS. 15, 16, 16A and 16B, sectional views of a representative platen 108 with non-limiting dimensions are depicted in an embodiment of the disclosure. All of the dimensions depicted in any of the accompanying figures of this disclosure are considered to be non-limiting, unless otherwise expressly stated.

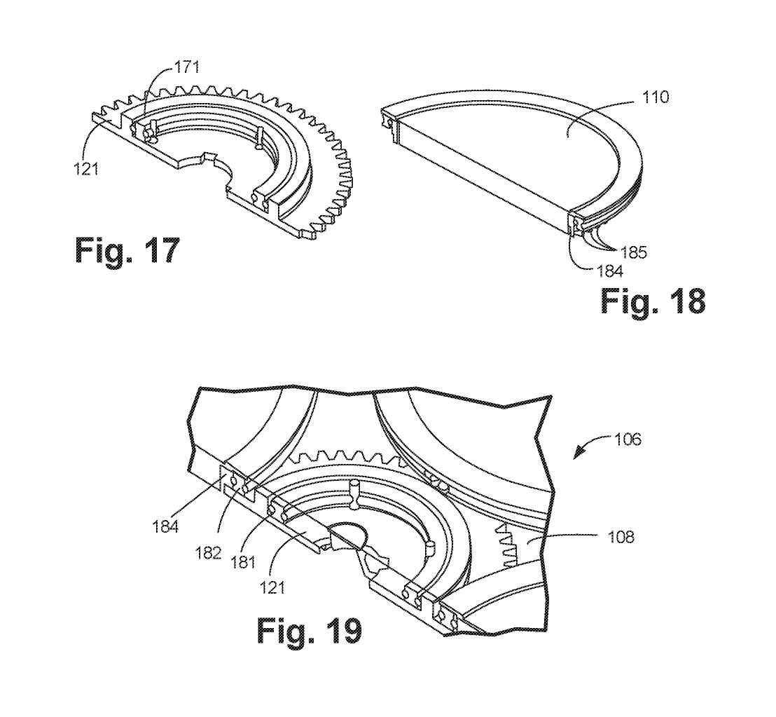

Referring to FIGS. 17-20, 20A and 20B, in an alternative embodiment, wafer carrier 106 can include race bearings 182. In this embodiment, race bearings 181 and 182 serve as the friction reducing bearings 122 and 123. A sun race bearing 181 can be configured to be received between the inside circumference 171 of raised portion 169 of sun gear 121 and the outer circumference 144 of the recessed sun gear compartment 142 of platen 108.

Additionally, in this alternative embodiment, ring gear collar 184 can surround a portion of wafer retention platform 110. Ring gear collar 184 can be characterized by a plurality of teeth 185 configured to mesh with the teeth 174 of sun gear 121. A plurality of planet race bearings 182 can be configured to be received between a portion of the ring gear collar 184 and openings 124 of platen 108.

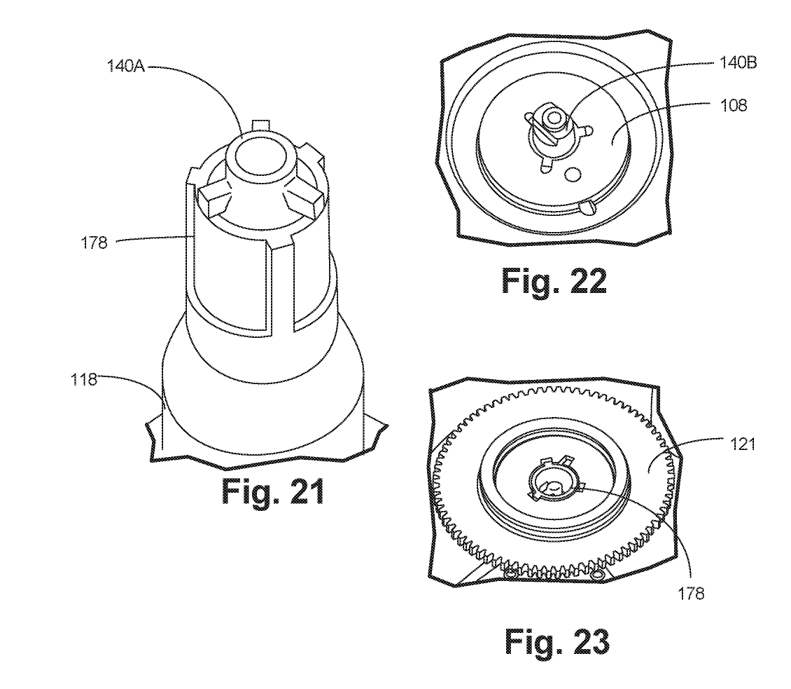

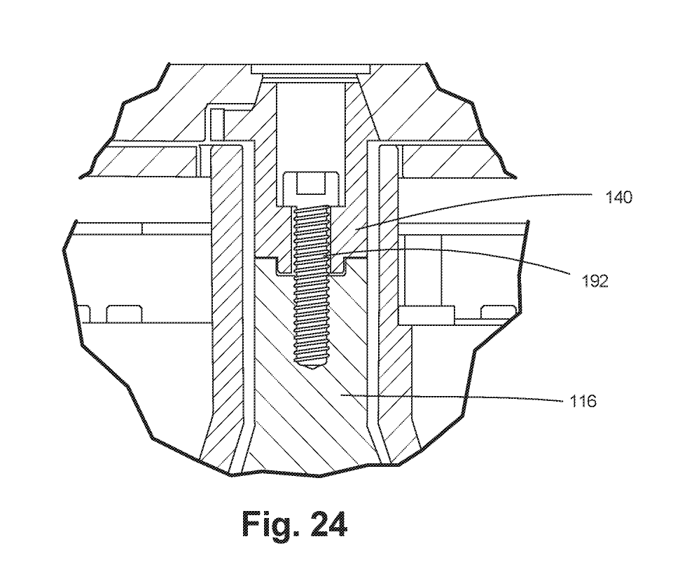

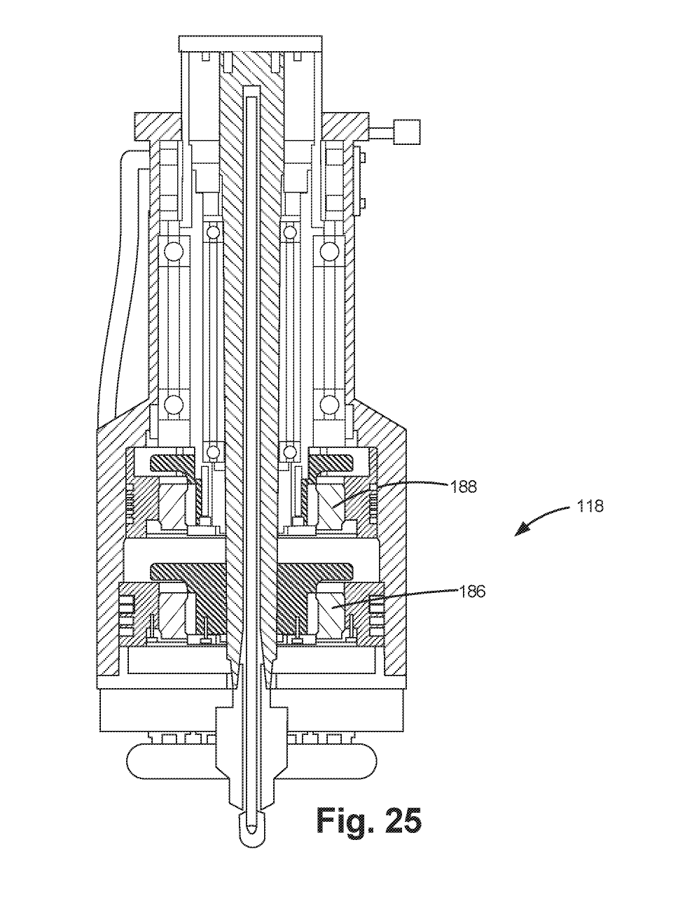

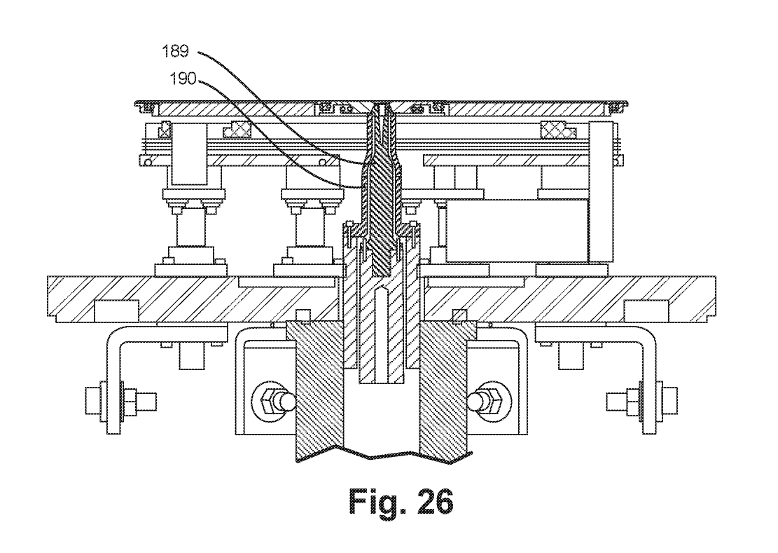

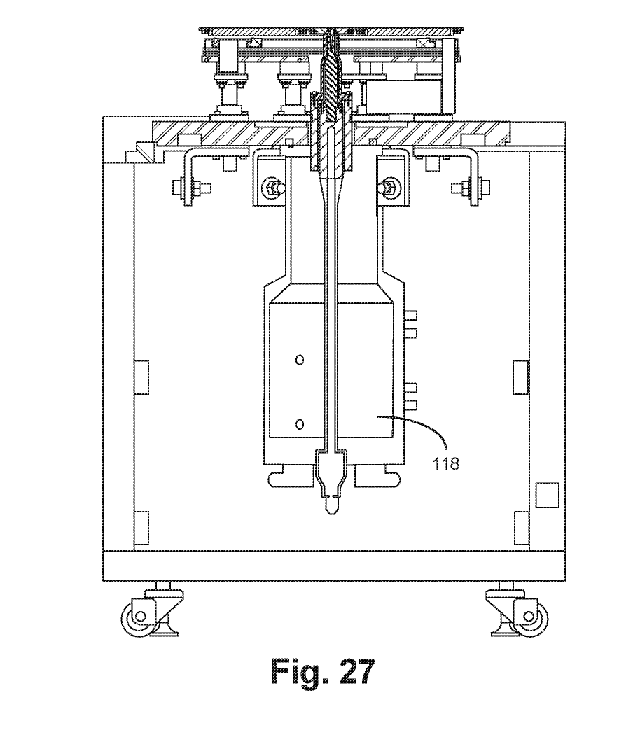

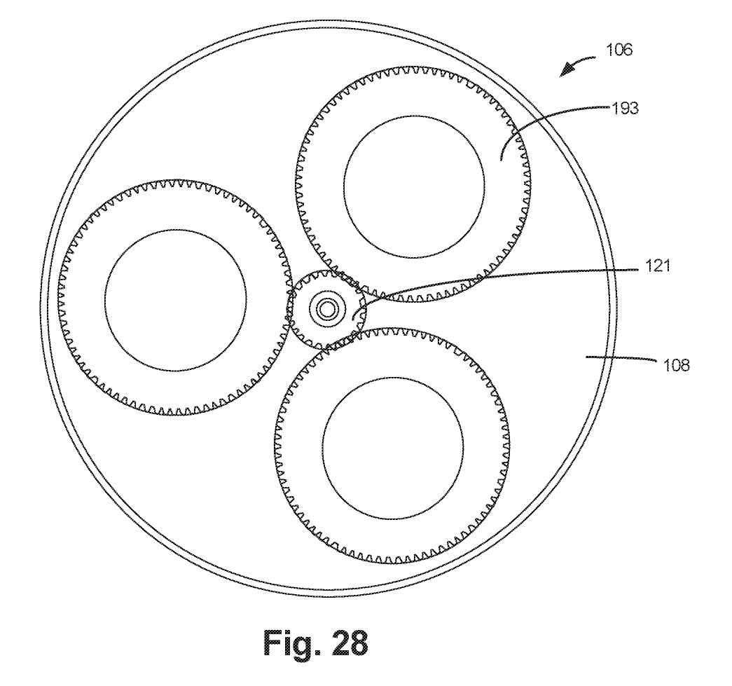

Referring to FIGS. 21-27, platen 108 can be rotatably driven by one motive force, while sun gear 121 can be rotatably driven by another motive force. The motive forces can be derived from a common motor 118 with two drive shafts: a center spindle 116 and a secondary spindle 178. The spindles 116 and 178 can operate simultaneously and independently of one another. For example, motor 118 can be a coaxial or dual core motor with a different rate of rotation for the center spindle 116 and secondary spindle 178. An example of a dual core motor 118 is depicted in FIG. 25. Dual core motor 118 can include a center spindle drive element 186 and a secondary spindle drive element 188. As depicted in FIG. 26, a center spindle adapter 189 and secondary spindle adapter 190 can serve as an extension of the center spindle 116 and secondary spindle 178. One skilled in the art will also appreciate that a modified coupling can permit the wafer carrier 106 to be used with a single shaft motor.

Center spindle 116, driven by motor 118, can be operably coupled to center spindle hub 140. In one embodiment, a bottom portion of platen hub 140B can be keyed to fit into a center spindle 116. Bolt 192 can use used to secure center spindle hub 140 to center spindle 116. Bolt 192 can be installed from the top surface of platen 132, through platen hub receiver center spindle hub receiver 138. In one embodiment, bolt 192 can be made of tungsten. Center spindle hub receiver 138 can be sealed by carrier plug 180. A top portion of platen hub 140A can be keyed to fit center spindle hub receiver 138 on platen 108. In this configuration, a motive force imparted from motor 118 can cause platen 108 to rotate. Yet, the coupling between the motor 118 and platen 108 can be separated lifting up on wafer carrier 106.

Sun gear 121, also driven by motor 118, can be operably coupled to sun gear drive shaft 182. In one embodiment, the hub opening 180 of sun gear 121 can be keyed to fit around sun gear drive shaft 182. In this configuration, motive force imparted from motor 118 can cause sun gear 121 to rotate. Yet, the coupling between the motor 118 and sun gear 121 can be separated lifting up on wafer carrier 106.

Referring to FIGS. 28-32, the size and gearing of the wafer retention platforms 110 can be varied to accommodate different rates of rotation and different size wafers. For example, FIG. 28 depicts an embodiment of a wafer carrier 106 wherein a sun gear 121 drives three planetary gears 193. In this embodiment, wafer carrier 106 can be approximately 465 mm in diameter and can accommodate 3 eight-inch diameter wafers.

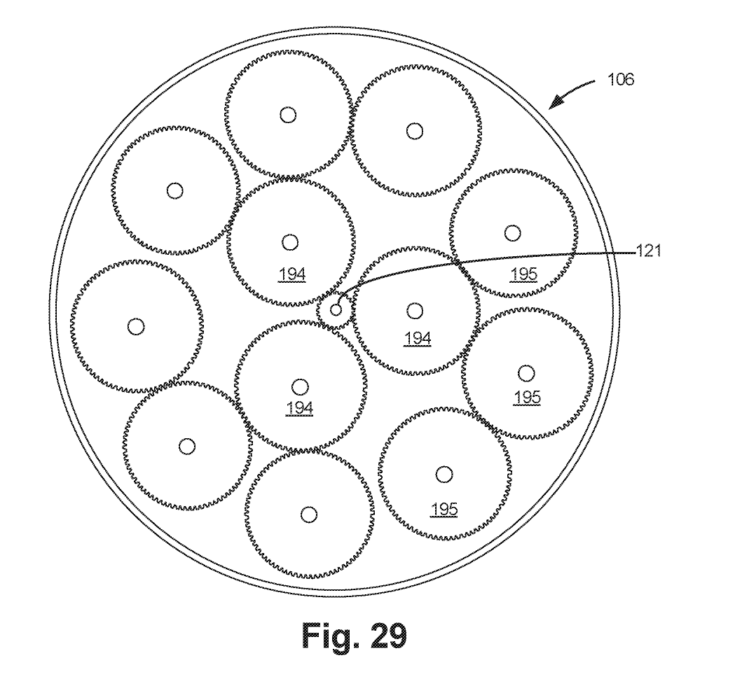

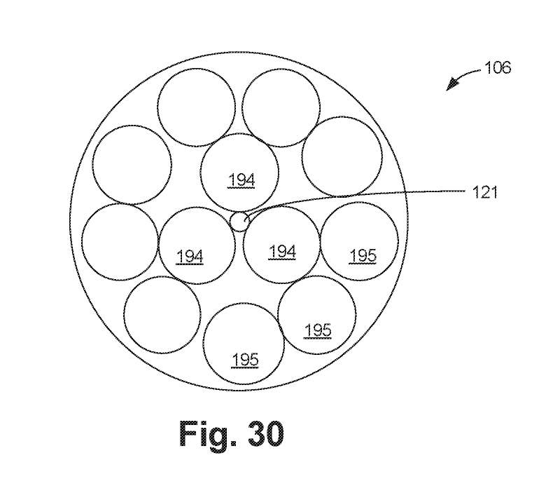

FIGS. 29-30 depict an embodiment of a wafer carrier 106 wherein a sun gear 121 drives twelve planetary gears 194, 195. In this embodiment, wafer carrier 106 can be approximately 695 mm in diameter and accommodate 12 six-inch diameter wafers. Sun gear 121 makes contact with three of the twelve planetary gears 194. Sun gear 121 can have eighteen teeth, the three planet gears 194 making direct contact with sun gear 121 can have sixty-one teeth. The remaining planet gears 195 can each have sixty-three teeth.

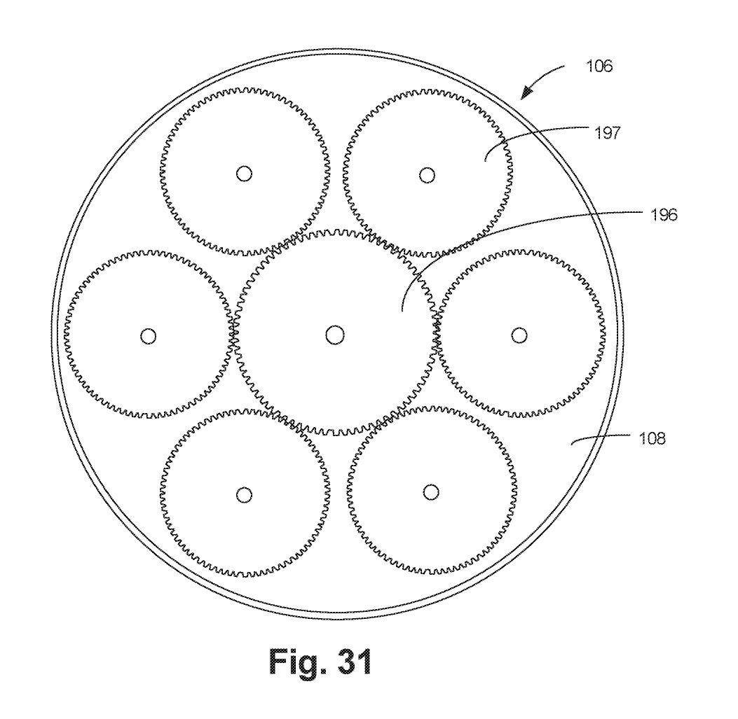

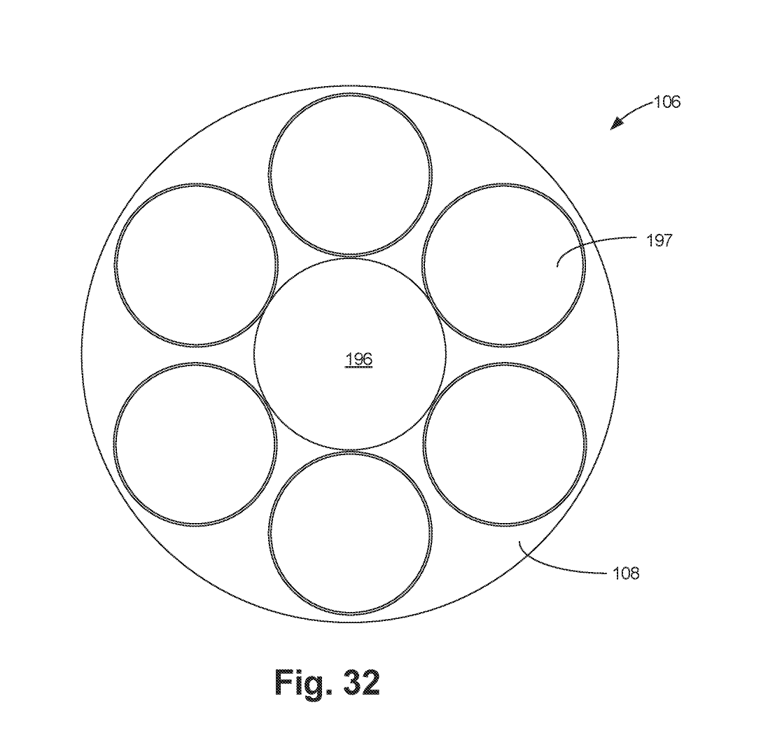

The size and number of teeth on sun gear 121 can also be varied to accommodate different rates of rotation of wafer retention platforms 110. FIGS. 31-32 depict an embodiment of a wafer carrier 106 wherein an enlarged sun gear 196 drives six planetary gears 197. In this embodiment, wafer carrier 106 can be approximately 695 mm in diameter and accommodate 6 eight-inch diameter wafers. Sun gear 196 can have 98 or 99 teeth and planet gears 197 can each have 80 teeth.

B. Multi-Ring Driven Wafer Retention Platforms

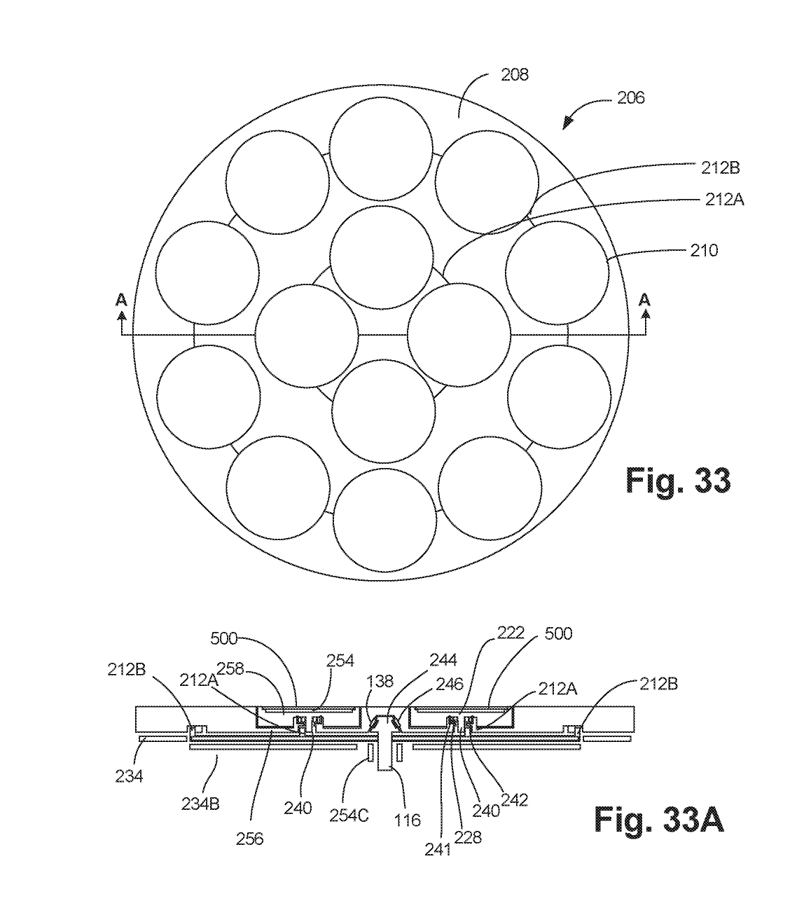

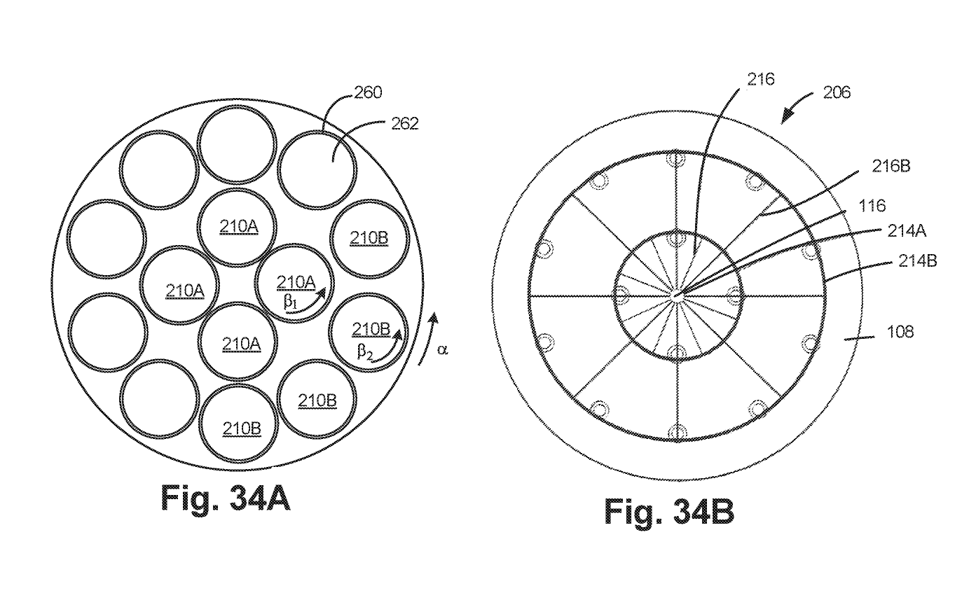

Referring to FIGS. 33-34B, in one embodiment, the wafer carrier 250 can include one or more rings 212 of wafer retention platforms 210. Each wafer retention platform 210 of a given ring 212 can be rotatably driven by a ring driver 214. Ring driver 214 can be coupled to center spindle 116 by a plurality of radial spokes 216A/216B. This configuration enables wafer carrier 206 to rotate at one rate of rotation α, while the plurality of wafer retention platforms 210 rotate at one or more second rate of rotation β₁/β₂. Where more than one ring driver 214A/214B is employed, wafer retention platforms 210A engaging with a first ring driver 214A can rotate about their axis at a first rate of rotation β₁, while the wafer retention platforms 210B in contact with a second ring driver 214B can rotate about access and a second rate of rotation β₂. Accordingly, this embodiment enables rotational averaging for the purpose of improving deposition uniformity without sacrificing wafer carrier 206 capacity.

As depicted in FIGS. 33-34B, one embodiment of the wafer carrier 206 is designed to have 14 wafer retention platforms 210A and 210B, respectively driven by ring drivers 214A and 214B, compatible with four-inch wafers. However, one skilled in the art will appreciate that other configurations are possible, including, but not limited to, a wafer carrier 206 designed to accommodate: 6 six-inch diameter wafers; 3 eight-inch diameter wafers; 26 four-inch diameter wafers; 12 six-inch diameter wafers; and 6 eight-inch diameter wafers. Wafer carrier 206 can be formed of silicon carbide coated graphite, solid silicon carbide, or another high temperature alloy, such as a Titanium-Zirconium-Molybdenum alloy. In one embodiment, assembly of the wafer carrier 206 does not require fasteners and can be easily disassembled for cleaning.

Each wafer retention platform 210 can have a top portion 254 and a bottom portion 256. Top portion 254 can be configured to serve as support for a wafer 500 during the chemical reaction process. Upper face 258 of the top portion 254 can be substantially smooth. Upper face 258 can be bound by a lip 260 extending upwards from top portion 254 along the circumference of retention platform 210. The substantially smooth upper face 258 surrounded by lip 260 can provide a pocket 262 for positioning and support of the wafer 500. In some embodiments, the shape of the pocket 262 can be contoured to achieve a uniform wafer temperature and to correct for thermal shadowing. Bottom portion 256 of the wafer retention platform 210 can be configured with a hub 240 to serve as a mechanism to rotationally drive wafer retention platform 210.

Wafer retention platform 210, including top portion 254, bottom portion 256, and hub 240, can be formed of a single piece of material. Additionally, wafer retention platform 210 can be designed to be low mass and highly resistant to high temperatures. For example, wafer retention platform 210 can be formed of silicon carbide coated graphite, solid silicon carbide, or another high temperature alloy, such as a Titanium-Zirconium-Molybdenum alloy. Alternatively, one skilled in the art will appreciate that wafer retention platform 210 can be comprised of multiple pieces affixed together.

Platen 208 can be formed of a single piece of material. For example, platen 208 can be cast of silicon carbide coated graphite, solid silicon carbide, or another high temperature alloy, such as a Titanium-Zirconium-Molybdenum alloy. Platen 208 can be generally disk shaped, and can have a plurality of wafer retention platform compartments 224. Each of the plurality of wafer retention platform compartments 224 can be appropriately sized to accommodate one wafer retention platform 210. A portion of wafer retention platform compartments 224 can extend all the way through platen 208, to enable hub 240 to extend below the bottom surface 236 of platen 208. By extending only the hub 240 through platen 248 (instead of the entire wafer retention platform 210 like in other embodiments), the bridges in the platen 208 between retention platform 210 can be made much larger and stronger; and therefore, less susceptible to breakage during acceleration and deceleration.

In one embodiment, a friction reducing bearing 222 can couple wafer retention platform 210 to platen 208. In this configuration, hub 240 can serve as the inner race of friction reducing bearing 222, while a silicon carbide coated graphite or solid silicon carbide collar 241 can serve as the outer race of the friction reducing bearing 222. Collar 241 can be formed with a single laser cut to accommodate differential expansion between hub 240 and collar 241. Ball bearings 228 can be made of silicon carbide, silicon nitride or some other refractory, high hardness material. In one embodiment, collar 241 can be placed in a compartment 242 on the bottom surface 236 of wafer retention platform 210. Friction reducing bearing 222 is designed to be small in diameter to reduce drag and the effect of thermal shadowing. The diameter of hub 240, however, is correlated to the size of the wafer retention platform 210; the larger and heavier the wafer retention platform 210, generally the larger diameter hub 240 must be. Additionally, it is noted that the friction reducing bearing 222 can be specifically positioned at the center of wafer retention platform 210, for the purpose of easing compensate for heat loss through pocket 262 shaping or other design features.

Wafer carrier 206 can be operably coupled to center spindle 116, which can be rotated by a motor 118. Motor 118 can provide rotation to center spindle 116 to produce a rate of rotation α. In some embodiments, center spindle 116 can have a conical head 244, including one or more saw tooth ratchets 246. In one embodiment, the one or more saw tooth ratchets 246 can be configured to enable wafer carrier 206 to freely rotate in one direction (i.e., freewheel) when the rate of rotation of the wafer carrier 206 exceeds the rate of rotation α of center spindle 116. When the rate of rotation α of center spindle 116 matches or exceeds the rate of rotation of the wafer carrier 206, one or more saw tooth ratchets 246 engage with grooves cut in center spindle hub receiver 138 to impart rotation on wafer carrier 206. In one embodiment, saw tooth ratchets 246 can be spring loaded to apply force against center spindle hub receiver 138; however, in other embodiments, because saw tooth ratchets 246 will, at times, be subjected to centrifugal forces a spring may not be required.

Ring drivers 212A and 212B can be operably coupled to center spindle 116 by a plurality of radial spokes 216A/216B. Alternatively, ring drivers 212A and 212B can be operably coupled to a secondary spindle 178 of dual core motor 118. The hubs 240 of each wafer retention platform 210A on the first ring 212A engage ring driver 214A, while the hubs 240 of each wafer retention platform 218B on the second ring 212B engage ring driver 214B. The engaging surfaces on hubs 240 and driver rings 214A and 214B can be knurled to increase friction between the mating surfaces. In contrast to gearing, the knurled contact surface enables for slip between the engaging surfaces without seizure or stripping gears.

When driving rings 214A and 214B are fixed in position relative to platen 208, no rotation of wafer retention platforms 210A and 210B will occur, even when the platen 208 itself is rotating. However, when there is a differential speed of rotation between platen 208 and driving rings 210A and 210B, driving rings 214A and 214B will cause rotation of wafer retention platforms 210A and 210B respectively. Thus, it is the difference in rotational speeds between platen 208 and driving rings 214A and 214B that affect the rotation speed of wafer retention platforms 210A and 210B. In this manner, hubs 240 roll along the inner circumference of driving rings 214A and 214B, thereby causing wafer retention platforms 210A and 210B to rotate about their hubs 240.

Further, in one embodiment, centrifugal forces experienced by the wafer retention platforms 210 when the wafer carrier 206 is rotating, can cause engagement of the hubs 240 with driving rings 214A and 214B. Therefore, in one embodiment, wafer carrier 206 must be rotating and there must be a differential between the rotation rates of platen 208 and driving rings 214A and 214B to effect wafer retention platform 210 rotation.

Differential speed concurrent with wafer carrier 206 rotation can be achieved in several modes. In one mode, termed an inertial drive, center spindle 116 speed is modulated slightly, for example as 600+/−10 RPM. When center spindle 116 speed drops from its peak value of 610 RPM to 590 RPM, the wafer carrier 206 will continue to free-wheel on center spindle 116; until the rate of rotation decreases to that of the rate of rotation α of center spindle 116, there will be a difference in rotational speeds between platen 208 and driving rings 214A and 214B, thereby allowing wafer retention platforms 210A and 210B to rotate about their hubs 240. When the carrier speed eventually decays to the center spindle 116 speed, the center spindle 116 is accelerated again to 610 RPM. The saw tooth ratchet 246 ensures that the wafer carrier 206 spins at the same speed in unison with the center spindle 116. This cycle is then repeated. Speed variation can be programmed as an S-shaped curve while accelerating from 590 PRM to 610 RPM to prevent damage to the grooves in wafer carrier 206 as a result of any impact with saw tooth ratchets 246. While decelerating from 610 RPM to 590 RPM, an exponential decay in rotational speed allows the wafer carrier 206 to freewheel and gradually equilibrate to the rate of rotation α of center spindle 116.

In another mode, of achieving a differential speed, the driving rings 214A and 214B are attached to a secondary spindle 178, which has a rate of rotation slightly different from that of the center spindle 116. This differential speed, will in turn enable wafer retention platforms 218A and 218B to rotate about their hubs 240.

In one embodiment, wafer carrier 206 is heated by three resistive filament heater zones 234 that irradiate the back surface 236 of wafer carrier 106 in between spokes 216. An outer heater 234A can be positioned outside of the outer diameter of ring driver 214B, and can be in close proximity to the bottom surface 236 of wafer carrier 106 to ensure good thermal coupling to the edge of wafer carrier 206. Middle 234B and inner 234C heater zones can be slightly further below bottom surface 236 of wafer carrier 206 to accommodate intervening drive rings 214 and hubs 240. For example, in one embodiment, middle 234B and inner 234C heater zones can be spaced 5 mm from bottom surface 236 of wafer carrier 206.

C. Sun and Planetary Gear Driven Wafer Retention Platforms

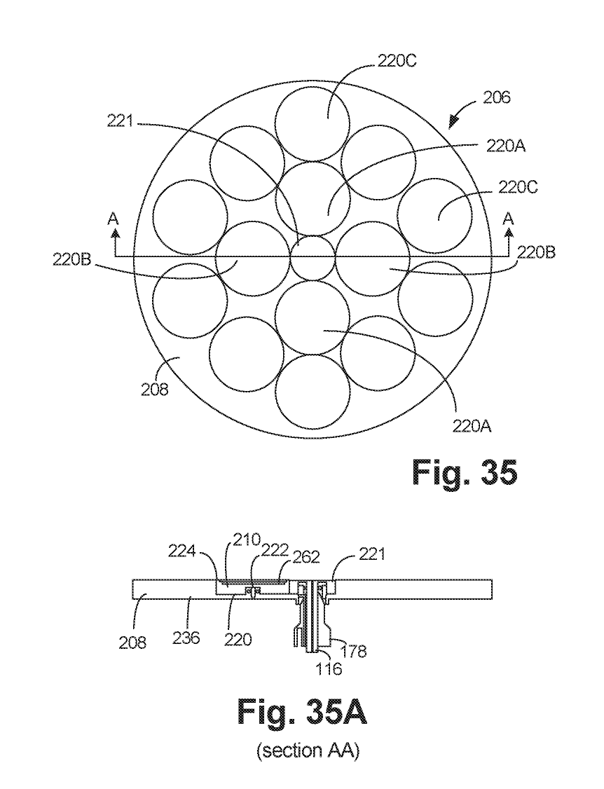

Referring to FIGS. 35 and 35A, in some embodiments, each of the plurality of wafer retention platform compartments 224 can be appropriately sized to accommodate one wafer retention platform 210. Wafer retention platform 210 can be formed of one or more piece of material. For example, wafer retention platform 210 can be made of silicon carbine, CVD silicon carbine, aluminum nitrate, silicon nitride, or other suitable material. A portion of wafer retention platform openings 224 can extend all the way through platen 208, to allow friction reducing bearing 222 to extend below bottom surface 236 of platen 208. By extending only friction reducing bearing 222 through platen 208 (instead of the entire wafer retention platform 220 like in other embodiments), the bridges in platen 208 between retention platforms 210 can be made much larger and stronger; and therefore, less susceptible to breakage during acceleration and deceleration.

FIGS. 35 and 35A depict an embodiment of a wafer carrier 206 wherein, a sun gear 221 drives fourteen planetary gears 220A, 220B and 220C. The sun gear 221 drives the four inner planetary gears 220A and 220B. Planetary gears 220A each drive three outer planetary gears 220C, and planetary gears 220B each drive two outer planetary gears 220C. All planetary gears 220A, 220B and 220C can have the same rotational speed. Friction reducing bearing 222 can be positioned at the center of each planetary gear 220A, 220B and 220C. Friction reducing bearing 222 can be designed to be small in diameter to reduce drag and the effect of thermal shadowing, as well as reduce cost and ease fabrication. In some embodiments, the shape of pocket 262 can be contoured to achieve a uniform wafer temperature and to correct for thermal shadowing. In some embodiments, the planetary gears 220A, 220B and 220C can be surrounded by a bushing (not depicted) to restrict gas from flowing from the top to the bottom of platen 208.

D. Gas Driven Wafer Retention Platforms

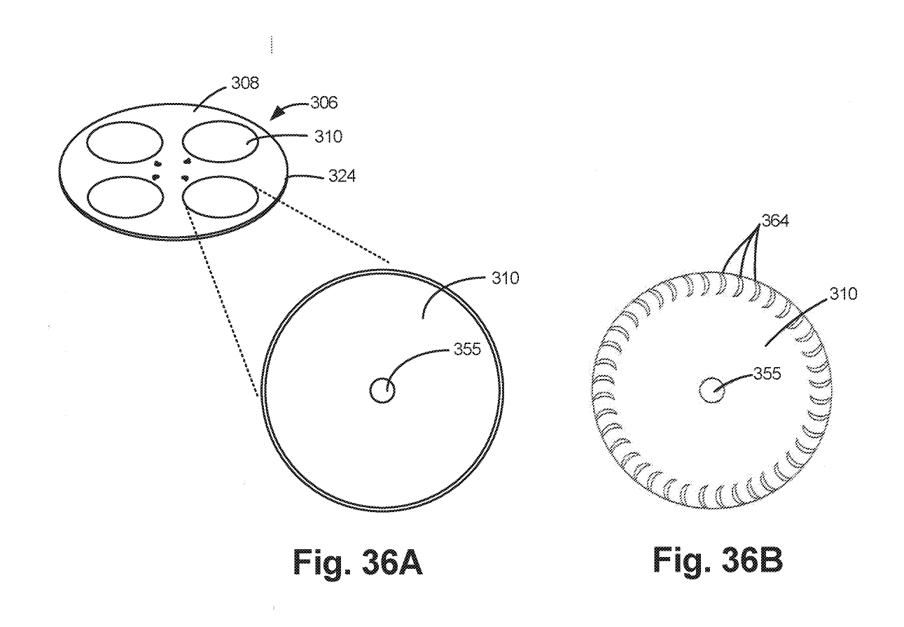

Referring to FIGS. 36A-40, in one embodiment, wafer carrier 306 can include a plurality of wafer retention platforms 310 of ultra light construction. Wafer retention platforms 310 can be pivotally connected to platen 308 by a friction reducing bearing 322. A portion of each wafer retention platform 310 can include a plurality of blades or fins 364, which when subjected to a gas flow cause rotation of wafer retention platforms 310 about friction reducing bearing 322.

Platen 308 can be formed of a single piece of material. For example, platen 308 can be cast of silicon carbide coated graphite. Platen 308 can be generally disk shaped, and can have a plurality of wafer retention platform compartments 324. Each of the plurality of wafer retention platform compartments 324 can be appropriately sized to accommodate at least a portion of one wafer retention platform 310. Wafer retention platform compartments 324 can be located on the top surface 332, the bottom surface 336, or both surfaces 332, 336 of platen 308. In one embodiment, wafer retention platform compartments 324 located proximate bottom surface 336 are sized to accommodate one or more nozzles 366. In another embodiment, two or more circular channels 381 and 382 can be located on the bottom surface, each accommodating one or more nozzles 366. A portion of each wafer retention platform pocket 310 can also extend all the way through platen 308. In one embodiment, a sliding bearing 338 can be positioned in the portion of the wafer retention platform compartment 324 that extends through platen 308.

Each wafer retention platform 310 has a top portion 354 and bottom portion 356 coupled together by center pin 355. Wafer retention platform 310 is designed to be light in weight. In one embodiment, the wafer retention platform 310 and wafer together weigh approximately 300 grams. Wafer retention platform 310 can be formed of one or more piece of material. For example, top portion 354 and bottom portion 356 can be made of silicon carbine, CVD silicon carbine, aluminum nitrate, silicon nitride, or other suitable material.

Top portion 354 can be generally disk shaped. For weight reasons, the depth of top portion 354 can be quite thin. For example, top portion can measure approximately 1 mm in thickness. Top portion 354 can be configured to serve as support for a wafer 500 during the chemical reaction process. Upper face 358 of top portion 354 can be substantially smooth. Upper face 358 can bound by a lip 360 extending upwards from top portion along the circumference of retention platform 310. The substantially smooth upper face 358 can be surrounded by lip 360 configured to provide a pocket 362 for positioning and support of the wafer 500. In some embodiments, the shape of pocket 362 can be contoured to achieve a uniform wafer temperature and to correct for thermal shadowing. Top portion 354 can be configured with a center hole 368.

Bottom portion 356 of wafer retention platform 310 can be generally disk shaped. For balance, the thickness of bottom portion 356 can be adjusted so that the weight of the bottom portion 356 equals the weight of the top portion 354 plus wafer 500. Bottom portion 356 includes a plurality of blades of fins 364. Bottom portion 356 can be configured with a center hole 369.

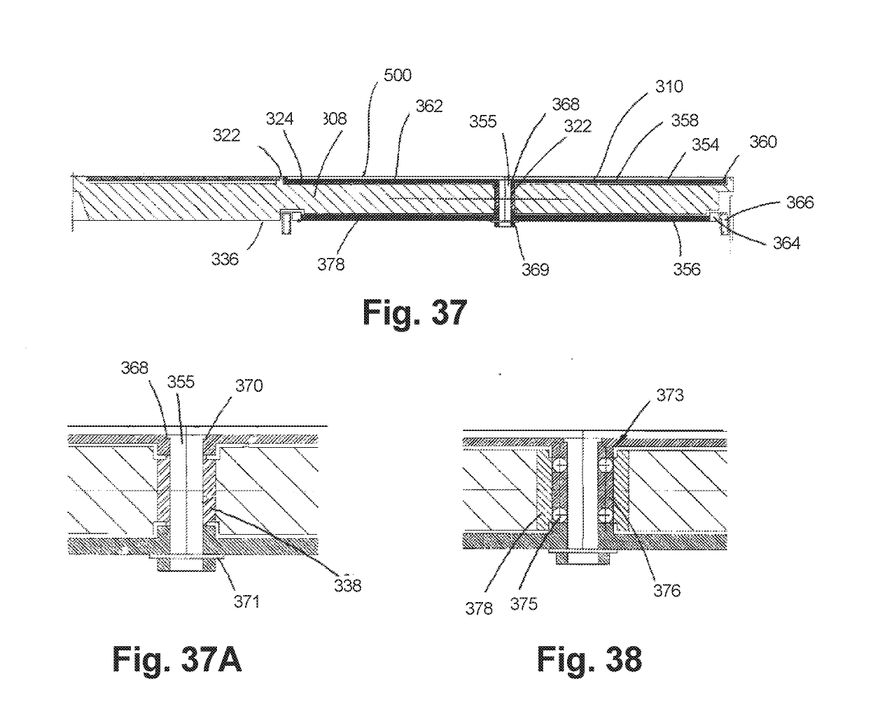

Referring to FIG. 37A, in one embodiment, top portion 354 and bottom portion 356 can be coupled by center pin 355. Center pin 355 can also serve as the pivot point for wafer retention platform 310. Center pin 355 can be formed of a suitable material, for example, CVD silicon carbide. In one embodiment, center pin 355 can have a top flange 370 design to prevent pin 355 from passing completely through center hole 368. In one embodiment, a pin or snap ring 371 can be coupled to center pin 355 to provide support to bottom portion 356 and keep the wafer retention platform 310 assembly together. Pin or snap ring 371 can be formed of a suitable material, for example, molybdenum.

Referring to FIG. 38, in another embodiment, top portion 354 and bottom portion 356 can be coupled by a ball bearing assembly 373. In this embodiment, outer ring 374 can be positioned in the portion of the wafer retention platform compartments 324 that extends through platen 308. Ball bearings 375 can be positioned inside of outer ring 374, and if need be appropriately spaced by spacers 376. As the pivot point for wafer retention platform 310, center pin 355 can be positioned inside of ball bearings 375, coupling top portion 354 and bottom portion 356 together.

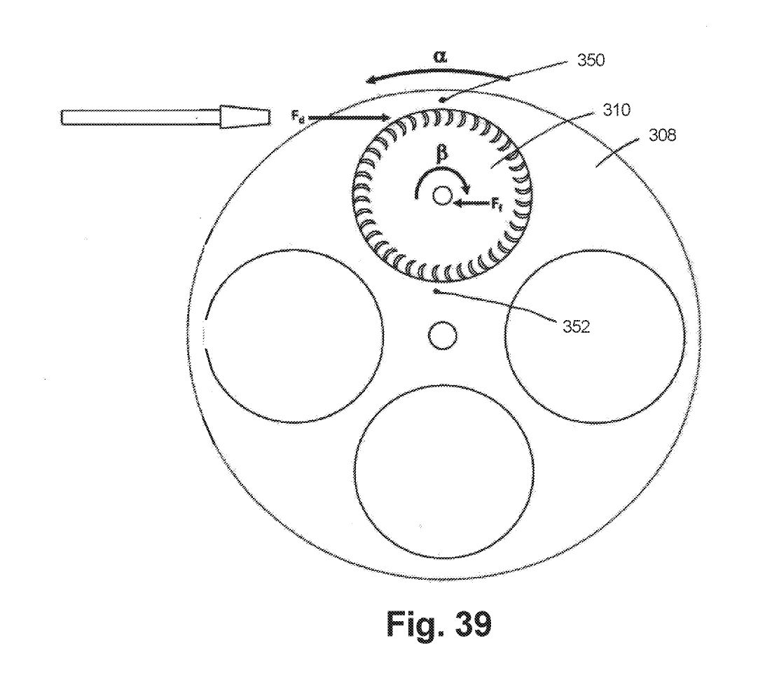

Referring to FIG. 39, wafer retention platform 310 can be configured with a plurality of blades or fins 364. To minimize the amount of force required to rotate wafer retention platform 310, blades 364 can be positioned proximate to the outer circumference of wafer retention platform 310. Blades 364 can extend laterally outward from outer circumference of wafer retention platform 310 (as depicted in FIG. 37), downward from the bottom face 378 of bottom portion 356 (as depicted in FIGS. 36B, 39), or a combination thereof. Blades 364 can be incorporated as part of bottom portion 356, or blades 364 can be coupled to bottom portion 356.

The platen 308 of wafer carrier 306 can be seated over center spindle 116, which can be rotated by a motor 118. Motor 118 can provide rotation to drive shaft 112 to produce a rate of rotation α. Force (Fd) applied to blades 364 can cause rotation of wafer retention platform 310 at rate of rotation β. Blades 364 can be straight or curved. The angle and curvature of blades 364 can be adjusted to produce the desired rate of rotation β of wafer retention platform 310.

The moment required to rotate wafer retention platform 310 at a given rate of rotation β equals the opposing frictional moment. The moment required to rotate wafer retention platform 310 is force (Fd) multiplied by the radius (rl) of wafer retention platform 310. The frictional moment is force (Ff) multiplied by the radius of friction reducing bearing 322. It is further noted that the lighter in weight that wafer retention platforms 310 can be constructed, and the less resistance imparted by friction reducing bearing 322, the less force (Fd) is required.

When platen 308 rotates at rate of rotation α, a given point on the outer perimeter 350 of platen 308 travels faster and farther than a given point 352 near the center of platen 308. Accordingly, when rotating platen 308 is emerged in a fluid, such as the gasses present in the reaction chamber 102 will experience a higher flow rate at point 350 that at point 352. This differential airflow can be used to provide rate of rotation β. In one embodiment, blades 364 can be configured to maximize fluid resistance to the flow proximate point 350, while minimizing fluid resistance proximate point 352, thereby overcoming the frictional moment and causing rotation of wafer retention platform 310.

In one embodiment, one or more nozzles 366 can be configured to provide gas flow over blades 364. Nozzles 366 can supplement the airflow differential discussed above, or provide sufficient flow to independently rotate wafer retention platforms 310 at rate of rotation β. Nozzles 366 can be constructed of a suitable material, such as molybdenum. In one embodiment, nitrogen gas can be directed through one or more nozzles 366. In one embodiment, the nitrogen gas is preheated prior to introduction into the reaction chamber 102 to prevent or reduce thermal deformation of the platen 308.

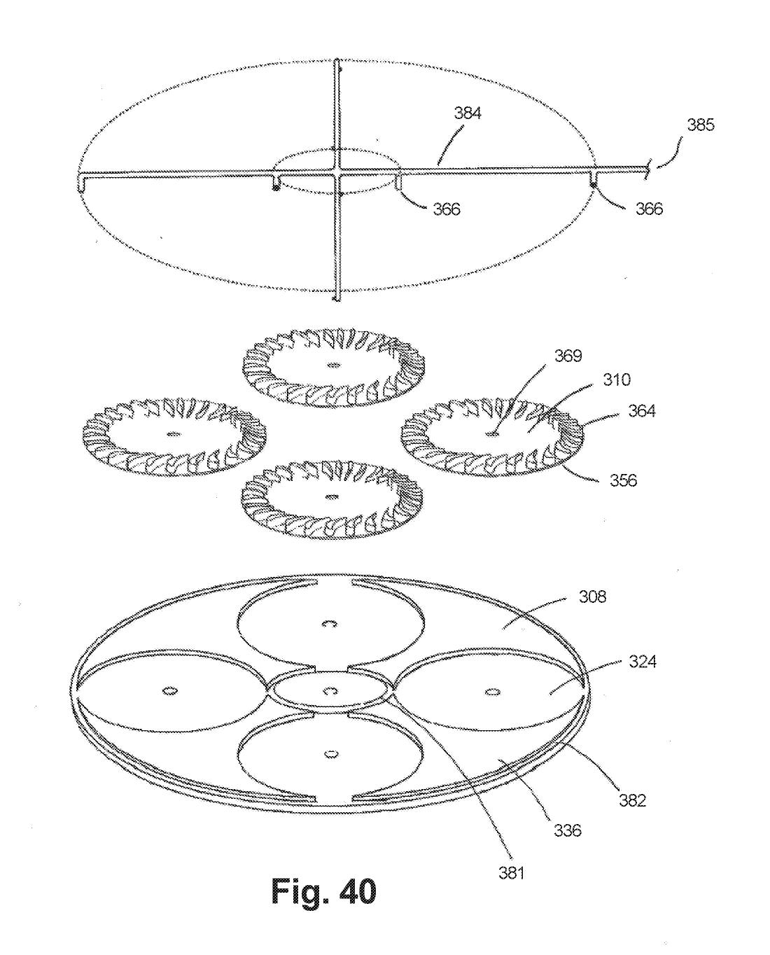

Referring to FIG. 40, in one embodiment, two nozzles 366 can be directed at each wafer retention platform 310. An array of nozzles 366 can be configured on gas line assembly 384. Gas line assembly 384 can be connectable to a gas supply through a gas inlet 385. The gas exiting each of the nozzles 366 can be directed to impinge on fins 364 of the wafer retention platforms 310 as the wafer retention platforms 310 rotate past a respective stationary nozzle 366. Impingement of the gas on the fins 364 of the wafer retention platforms 310 can cause rotation of the wafer retention platforms 310 independent of the rotation of platen 308.

In one embodiment, two nozzles 366 can be positioned to impinge fins 364 of the passing wafer retention platforms 310 at diametrically opposed locations. In this embodiment, the two nozzles 366 are oriented to face in opposite directions to provide complementary thrust to the wafer retention platforms.

In one embodiment, platen 308 is configured with circular channels 381 and 382 formed on the bottom face of the platen. The circular channels 381 and 382 function to direct the gas exiting nozzles 366 to fins 364 for more efficient momentum transfer of the gas to fins 364. The channels 381 and 382 can be dimensioned so that, when assembled, nozzles 366 of gas line assembly 384 are accommodated within the boundaries of circular channels 381 and 382 for enhanced momentum transfer of the gas to channels 381 and 382.

In another embodiment, four nozzles can be directed at fins 364. In yet another embodiment, with two rings 212 of wafer retention platforms (see FIG. 33 depicting a wafer retention platforms with two rings) six nozzles can be positioned proximate wafer carrier 306; four of the nozzles can be directed at the blades 364 proximate outer ring 212B and two nozzles can be directed at the blades 364 proximate inner ring 212A.

Persons of ordinary skill in the relevant arts will recognize that embodiments may comprise fewer features than illustrated in any individual embodiment described above. The embodiments described herein are not meant to be an exhaustive presentation of the ways in which the various features may be combined. Accordingly, the embodiments are not mutually exclusive combinations of features; rather, embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Moreover, reference in the specification to “one embodiment,” “an embodiment,” or “some embodiments” means that a particular feature, structure, or characteristic, described in connection with the embodiment, is included in at least one embodiment of the teaching. The appearances of the phrase “in one embodiment” in various places in the specification are not necessarily all referring to the same embodiment.

It should be understood that the individual steps used in the methods of the present teachings may be performed in any order and/or simultaneously, as long as the teaching remains operable. Furthermore, it should be understood that the apparatus and methods of the present teachings can include any number, or all, of the described embodiments, as long as the teaching remains operable.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of Section 112, sixth paragraph of 35 U.S.C. are not to be invoked unless the specific terms “means for” or “step for” are recited in a claim.

1. A wafer carrier for a plurality of wafers, the wafer carrier comprising:
a platen with a plurality of openings, the platen configured to rotate about a first axis;
a plurality of wafer retention platforms, each of the plurality of wafer retention platforms rotatably coupled to one of the plurality of openings by a friction reducing bearing assembly and configured to rotate about a respective second axis;
wherein the platen, the plurality of wafer retention platforms and the friction reducing bearing assemblies are constructed of the same material.

2. The wafer carrier of claim 1, wherein the platen, plurality of wafer retention platforms and the friction reducing bearing assemblies are constructed of silicon carbide.

3. The wafer carrier of claim 1, wherein each of the friction reducing bearing assemblies comprise a plurality of ball bearings, wherein the plurality of ball bearings reside within a ball bearing channel defined between an inner circumferential surface of the plurality of openings of the platen and an outer circumferential surface of each of the plurality of wafer retention platforms.

4. The wafer carrier of claim 3, wherein the plurality of ball bearings are inserted into the ball bearings channel via one or more bearing filling channels.

5. The wafer carrier of claim 4, wherein the one or more bearing filling channels are plugged by one or more channel plugs after the plurality of ball bearings are inserted.

6. The wafer carrier of claim 1, wherein the platen rotates at a first rotational speed and at least one of the plurality of wafer retention platforms rotates at a second rotational speed.

7. The wafer carrier of claim 1, wherein each of the plurality of wafer retention platforms comprises a planetary gear.

8. The wafer carrier of claim 7, wherein the each of the planetary gears is rotated by a centrally located sun gear.

9. The wafer carrier of claim 8, wherein the sun gear is constructed of silicon carbide.

10. The wafer carrier of claim 8, wherein the sun gear is operably coupled to the platen via a sun gear friction reducing bearing.

11. The wafer carrier of claim 8, wherein the sun gear friction reducing bearing comprises a plurality of ball bearings, wherein the plurality of ball bearings reside within a sun gear ball bearing channel defined between a portion of the platen and a portion of the sun gear.

12. The wafer carrier of claim 11, wherein the plurality of ball bearings are inserted into the sun gear ball bearings channel via one or more sun gear bearing filling channels.

13. The wafer carrier of claim 12, wherein the sun gear bearing filling channels is plugged by a channel plug after the ball bearings are inserted.

14. The wafer carrier of claim 8, wherein the platen and the sun gear are independently rotated by a dual core motor.

15. A wafer carrier for a plurality of wafers, the wafer carrier comprising:
a platen with a plurality of openings and a plurality of bearing filling channels, the platen configured to rotate about a first axis;
a plurality of wafer retention platforms, each of the plurality of wafer retention platforms rotatably coupled to one of the plurality of openings by a plurality of ball bearings added through the plurality of bearing filling channels and configured to rotate about a respective second axis.

16. The wafer carrier of claim 15, wherein the platen, plurality of wafer retention platforms and plurality of ball bearings are constructed of silicon carbide.

17. The wafer carrier of claim 15, wherein the ball bearings reside within a ball bearing channel defined between an inner circumferential surface of the plurality of openings of the platen and an outer circumferential surface of each of the plurality of wafer retention platforms.

18. The wafer carrier of claim 15, wherein the plurality of bearing filling channels are plugged by one or more channel plugs after the plurality of ball bearings are added.

19. The wafer carrier of claim 15, wherein the platen rotates a first rotational speed and at least one of the plurality of wafer retention platforms rotates at a second rotational speed.

20. The wafer carrier of claim 15, wherein each of the plurality of wafer retention platforms comprises a planetary gear.

21. The wafer carrier of claim 15, wherein at least one of the planetary gears is rotated by a centrally located sun gear.

22. The wafer carrier of claim 21, wherein the sun gear is constructed of silicon carbide.

23. A wafer carrier for a plurality of wafers, the wafer carrier comprising:
a platen configured to rotate about a first axis, the platen having a plurality of openings organized along one or more circumferential rings centered on the first axis;
a plurality of wafer retention platforms each having a hub, wherein each wafer retention platform is rotatably coupled to one of the plurality of openings and is configured to rotate relative to the platen about its hub; and
one or more ring drivers rotatably coupled to the platen and configured to engage the hubs of the wafer retention platforms organized along at least one of the one or more circumferential rings, so as to rotate the wafer retention platforms about their respective hubs.

24. The wafer carrier of claim 23, wherein a differential in rotational speed between the platen and the one or more ring drivers causes the platen to rotate at a first rotational speed and the plurality of wafer retention platforms to rotate at a second rotational speed.

25. The wafer carrier of claim 23, comprising two ring drivers configured to rotate a first set of wafer retention platforms organized along an inner circumferential ring centered on the first axis of the platen about their respective hubs, and a second set of wafer retention platforms organized along an outer circumferential ring centered on the first axis of the platen about their respective hubs.

26. The wafer carrier of claim 25, wherein the first set of wafer retention platforms rotate about the respective hubs at a first rotational speed, and the second set of wafer retention platforms rotate about the respective hubs at a second rotational speed.

27. The wafer carrier of claim 23, wherein the platen and each of the plurality of wafer retention platforms are coupled to one another via a friction reducing assembly.

28. The wafer carrier of claim 23, wherein the platen and the one or more ring drivers are independently rotated by a dual core motor.

29. A wafer carrier for a plurality of wafers, the wafer carrier comprising:
a platen with a plurality of openings, the platen configured to rotate about a first axis;
a plurality of wafer retention platforms, each of the plurality of wafer retention platforms rotatably coupled to a respective one of the plurality of openings and, each of the plurality of wafer retention platforms including a set of blades,
wherein each of the plurality of wafer retention platforms is configured to rotate about a respective second axis when a force is applied to its set of blades.

30. The wafer carrier of claim 29, wherein each blade of the respective sets of blades is shaped to produce the desired rate of rotation of its respective wafer retention platform.

31. The wafer carrier of claim 29, wherein each of the wafer retention platforms are coupled to the platen via a friction reducing bearing.

32. The wafer carrier of claim 29, wherein the silicon wafer can be positioned in each wafer retention platform.

33. The wafer carrier of claim 29, wherein a silicon wafer and each wafer retention platform has a combined weight 300 grams or less.

34. The wafer carrier of claim 29, wherein one or more nozzles are directed at the sets of blades, so as to apply a fluid flow force on the blades.
